(19) United States
(12) Patent Application Publication
(10) Pub. No.: US 2004/0233717 A1
(43) Pub. Date: Nov. 25, 2004

(54) Semiconductor memory device having functions of reading and writing at same time, and microprocessor

(75) Inventors: Yoshinao Morikawa, Ikoma-shi (JP); Masaru Nawaki, Nara-shi (JP); Hiroshi Iwata, Ikoma-gun (JP); Akihide Shibata, Nara-shi (JP)

Correspondence Address: MORRISON & FOERSTER LLP, 755 PAGE MILL RD, PALO ALTO, CA, 94304-1018, US

(73) Assignee: SHARP KABUSHIKI KAISHA, Osaka-shi (JP)

(21) Appl. No.: 10/846,875

(22) Filed: May 13, 2004

(30) Foreign Application Priority Data
May 19, 2003 (JP) 2003-140896

(51) Int. Cl. G11C 16/10

(52) U.S. Cl. 365/185.11

(57) ABSTRACT

A semiconductor memory device of the present invention includes a first memory array, a first address register for storing therein a first address of the first memory array, a second memory array, a second address register for storing therein a second address of the second memory array, a multiplexer connected to the first memory array and the second memory array and to a memory output unit for selectively outputting the first memory array or the second memory array, and an array selection circuit for selecting the first memory array for re-programming in accordance with an input address and selecting the second memory array for a reading operation. The array selection circuit sends the first address to the, first address register, sends the second address to the second address register, and further, controls the multiplexer, so as to allow the second memory array to be connected to the memory output unit during re-programming of the first memory array. Each of the first memory array and the second memory array includes a plurality of nonvolatile memory cells. It is therefore possible to improve processing speed by enabling data to be read in a re-programming process on the semiconductor memory device.

### CROSS-REFERENCE TO RELATED APPLICATION

This application is related to Japanese patent application No.2003-140896 filed on May 19, 2003, whose priority is claimed under 35 USC § 119, the disclosure of which is incorporated by reference in its entirety.

### BACKGROUND OF THE INVENTION

1. Field of the Invention

The present invention relates to a semiconductor memory device, a display device and a portable electronic apparatus. More particularly, the present invention relates to a semiconductor memory device having the functions of reading and writing data at the same time. More specifically, the present invention concerns: a semiconductor memory device obtained by arranging nonvolatile memory cells each including a gate electrode formed on a semiconductor layer via a gate insulating film, a channel region disposed under the gate electrode, diffusion regions disposed on both sides of the channel region and having a conductive type opposite to that of the channel region, and memory functional units formed on both sides of the gate electrode and having the function of retaining charges; and a display device and a portable electronic apparatus each having the semiconductor memory device.

The present invention also concerns a semiconductor memory device including a memory array obtained by arranging semiconductor memory cells, and a peripheral circuit capable of reading data while data is being written to the memory array.

2. Description of the Related Art

Conventionally, as a memory for continuously retaining data, a nonvolatile memory has been employed for a semiconductor memory device. As a nonvolatile memory, typically, a flash memory is used.

In a flash memory, as shown in FIG. 22, a floating gate 902, an insulating film 907 and a word line (control gate) 903 are formed in this order on a semiconductor substrate 901 via a gate insulating film. On both sides of the floating gate 902, a source line 904 and a bit line 905 are formed by a diffusion region, thereby constructing a memory cell. A device isolation region 906 is formed around the memory cell (see, for example, Japanese Unexamined Patent Publication No. HEI 5(1993)-304277).

The memory cell retains data according to the more or less a charge amount in the floating gate 902. In a memory cell array constructed by arranging memory cells, by selecting a specific word line and a specific bit line and applying a predetermined voltage, an operation of rewriting/reading a desired memory cell can be performed.

In such a flash memory, when a charge amount in the floating gate changes, a drain current (Id)-gate voltage (Vg) characteristic as shown in FIG. 23 is displayed. In the figure, a solid line shows the characteristic in a writing state, and a dashed line shows the characteristic in an erasing state. When the amount of negative charges in the floating gate increases, the threshold increases, and an Id-Vg curve shifts almost in parallel in the direction of increasing Vg.

In such a flash memory, however, it is necessary to dispose the insulating film 907 for separating the floating gate 902 and the word line 903 from the functional viewpoint. In addition, in order to prevent leakage of charges from the floating gate 902, it is difficult to reduce the thickness of the gate insulating film. It is therefore difficult to effectively reduce the thickness of the insulating film 907 and the gate insulating film, and it disturbs reduction in size of the memory cell.

One of nonvolatile memories is a flash electrically erasable and programmable read only memory (flash EEPROM). The flash EEPROM can be programmed by the user. Once programmed, the flash EEPROM retains data until the data is erased. After the programming is performed once, all of data or a predetermined block in the flash EEPROM can be electrically erased and new data can be re-programmed by one relatively prompt operation. As an example, the flash EEPROM is applied as an in-system re-programmable nonvolatile memory device to a microprocessor base system. Since the flash EEPROM is electrically erasable and re-programmable, it can be said as means of high cost effectiveness for storing/updating a program. The flash EEPROM can be re-programmed by a central processing unit (CPU) and the re-programming is called in-system writing (ISW).

However, there is a problem in that data cannot be read from the flash EEPROM while a CPU is performing programming or re-programming on the flash EEPROM. That is, while programming or re-programming is being performed on the flash EEPROM, a process on the flash EEPROM cannot be performed. In a sense, the CPU is idle.

For example, erase time of the flash EEPROM is generally 0.5 to 30 seconds. On the other hand, time required to program one byte in a flash EEPROM is about 16 to 400 microseconds. The erase time of the flash EEPROM is much longer than the programming time of the flash EEPROM.

Therefore, when data is being written or erased to/from a flash EEPROM, an operation of reading another unaccessed flash EEPROM having another address space cannot be performed. Due to slow access to a memory, the performance (processing speed) of a whole computer system using the flash EEPROM deteriorates.

### SUMMARY OF THE INVENTION

The present invention has been achieved in consideration of the viewpoints and its object is to provide a nonvolatile semiconductor memory device capable of reading data which has not been subjected to re-programming during re-programming operation.

Another object of the present invention is to provide a semiconductor memory device and a portable electronic device of which size can be easily reduced.

The present invention provides a semiconductor memory device comprising: a first memory array; a first address register for storing therein a first address of the first memory array; a second memory array; a second address register for storing therein a second address of the second memory array; a multiplexer connected to the first memory array and the second memory array and to a memory output unit for selectively outputting the first memory array or the second memory array; and an array selection circuit for selecting the first memory array for re-programming in accordance with an input address and selecting the second memory array for a reading operation, wherein the array selection circuit sends the first address to the first address register, sends the second address to the second address register, and further, controls the multiplexer, so as to allow the second memory array to be connected to the memory output unit during re-programming of the first memory array, and each of the first memory array and the second memory array includes a plurality of nonvolatile memory cells each including a gate electrode formed on a semiconductor layer via a gate insulating film, a channel region disposed under the gate electrode, diffusion regions disposed on both sides of the channel region and having a conductive type opposite to that of the channel region, and memory functional units formed on both sides of the gate electrode and having the function of retaining charges.

From another point of view, the present invention also provides a microprocessor comprising: a control unit; a communication port; buses connected to the control unit and the communication port; and a first memory array and a second memory array, both of which are connected to the control unit and the communication port via the buses, wherein each of the first memory array and the second memory array includes a plurality of nonvolatile memory cells each including a gate electrode formed on a semiconductor layer via a gate insulating film, a channel region disposed under the gate electrode, diffusion regions disposed on both sides of the channel region and having a conductive type opposite to that of the channel region, and memory functional units formed on both sides of the gate electrode and having the function of retaining charges, and the control unit has access to information stored in the second memory array during re-programming of the first memory array.

With this configuration, a data reading operation can be performed during programming of data, thereby increasing the speed of processing in a system using the memory array according to the present invention.

### BRIEF DESCRIPTION OF THE DRAWINGS

FIG. 1 is a schematic sectional view showing a main part of a memory cell (first embodiment) in a semiconductor memory device according to the present invention;

FIGS. 2A and 2B are schematic sectional views each showing a main part of a modification of the memory cell (first embodiment) in the semiconductor memory device according to the present invention;

FIG. 3 is a diagram for describing a writing operation of the memory cell (first embodiment) in the semiconductor memory device according to the present invention;

FIG. 4 is a diagram for describing a writing operation of the memory cell (first embodiment) in the semiconductor memory device according to the present invention;

FIG. 5 is a diagram for describing an erasing operation of the memory cell (first embodiment) in the semiconductor memory device according to the present invention;

FIG. 6 is a diagram for describing an erasing operation of the memory cell (first embodiment) in the semiconductor memory device according to the present invention;

FIG. 7 is a diagram for describing a reading operation of the memory cell (first embodiment) in the semiconductor memory device according to the present invention;

FIG. 8 is a schematic sectional view showing a main part of a memory cell (second embodiment) in the semiconductor memory device according to the present invention;

FIG. 9 is an enlarged schematic sectional view of the main part shown in FIG. 8;

FIG. 10 is an enlarged schematic sectional view of a modification of the main part shown in FIG. 8;

FIG. 11 is a graph showing electric characteristics of the memory cell (second embodiment) in the semiconductor memory device according to the present invention;

FIG. 12 is a schematic sectional view showing a main part of a modification of the memory cell (second embodiment) in the semiconductor memory device according to the present invention;

FIG. 13 is a schematic sectional view showing a main part of a memory cell (third embodiment) in the semiconductor memory device according to the present invention;

FIG. 14 is a schematic sectional view showing a main part of a memory cell (fourth embodiment) in the semiconductor memory device according to the present invention;

FIG. 15 is a schematic sectional view showing a main part of a memory cell (fifth embodiment) in the semiconductor memory device according to the present invention;

FIG. 16 is a schematic sectional view showing a main part of a memory cell (sixth embodiment) in the semiconductor memory device according to the present invention;

FIG. 17 is a schematic sectional view showing a main part of a memory cell (seventh embodiment) in the semiconductor memory device according to the present invention;

FIG. 18 is a schematic sectional view showing a main part of a memory cell (eighth embodiment) in the semiconductor memory device according to the present invention;

FIG. 19 is a graph showing electric characteristics of a memory cell (ninth embodiment) in the semiconductor memory device according to the present invention;

FIG. 20 is a schematic configuration diagram showing a liquid crystal display (twelfth embodiment) in which the semiconductor memory device according to the present invention is assembled;

FIG. 21 is a schematic configuration diagram showing a portable electronic apparatus (thirteenth embodiment) in which the semiconductor memory device according to the present invention is assembled;

FIG. 22 is a schematic sectional view showing a main part of a conventional flash memory;

FIG. 23 is a graph showing electric characteristics of a conventional flash memory;

FIG. 24 is a circuit diagram showing a semiconductor memory device (tenth embodiment) according to the present invention;

FIG. 25 is a block diagram showing a microprocessor system having a memory array according to the present invention;

FIG. 26 is a block diagram showing the internal configuration of the memory array shown in FIG. 25;

FIG. 27 is a block diagram showing an array selection circuit shown in FIG. 26;

FIG. 28 is a block diagram showing a path logic circuit shown in FIG. 26; and

FIG. 29 is a block diagram showing a 1-bit circuit in an address register shown in FIG. 26.

### DETAILED DESCRIPTION OF THE INVENTION

A semiconductor memory device of the present invention is mainly constructed by a nonvolatile memory cell, a memory block constructed by a plurality of nonvolatile memory cells, a circuit for reading the memory block, an output multiplexer for selecting a result of the reading and sending it as a device output, an address register circuit for programming and erasing, a control circuit for controlling the programming and erasing, and a switch for controlling a program voltage and an erase voltage.

Programming denotes herein to set a state where a desired amount of charges is accumulated in the nonvolatile memory cell. The semiconductor memory device according to the present invention basically employs an MOS circuit and, preferably, all of circuits including the MOS circuit are mounted on a single semiconductor substrate.

The nonvolatile memory cell in the semiconductor memory device according to the present invention is mainly constructed by a semiconductor layer, a gate insulating film, a gate electrode, a channel region, a diffusion region and a memory functional unit. Herein, the channel region is normally a region of the same conductive type as that of the semiconductor layer and denotes a region immediately below the gate electrode. The diffusion region denotes a region of the conductive type opposite to that of the channel region.

Concretely, the nonvolatile memory cell of the present invention may be constructed by a region of a first conductive type as a diffusion region, a region of a second conductive type as a channel region, a memory functional unit disposed across a border of the regions of the first and second conductive types, and an electrode provided via a gate insulating film. It is suitable that the memory cell of the present invention is constructed by a gate electrode formed on a gate insulating film, two memory functional units formed on both sides of the gate electrode, two diffusion regions disposed on the opposite sides of the gate electrode of the memory functional units, and a channel region disposed below the gate electrode. Hereinafter, the nonvolatile memory cell of the present invention will be referred to as a sidewall memory cell.

In the semiconductor device of the present invention, the semiconductor layer is formed on the semiconductor substrate, preferably, on a well region of the first conductive type formed in the semiconductor substrate.

The semiconductor substrate is not particularly limited as long as it can be used for a semiconductor device, and an example thereof includes a bulk substrate made of an element semiconductor such as silicon, germanium or the like or a compound semiconductor such as silicon germanium, GaAs, InGaAs, ZnSe or GaN. As a substrate having a semiconductor layer on its surface, various substrates such as an SOI (Silicon on Insulator) substrate, an SOS substrate and a multilayer SOI substrate, or a glass or plastic substrate having thereon a semiconductor layer may be used. In particular, a silicon substrate and an SOI substrate having a semiconductor layer on its surface are preferable. The semiconductor substrate or semiconductor layer may be single crystal (formed by, for example, epitaxial growth), polycrystal, or amorphous although an amount of current flowing therein varies a little.

On the semiconductor layer, preferably, a device isolation region is formed. Further, a single layer or multilayer structure may be formed by a combination of devices such as a transistor, a capacitor and a resistor, a circuit formed by the devices, a semiconductor device, and an interlayer insulating film. The device isolation region can be formed by any of various device isolation films such as an LOCOS film, a trench oxide film and an STI film. The semiconductor layer may be of the P or N conductive type. In the semiconductor layer, preferably, at least one well region of the first conductive type (P or N type) is formed. As impurity concentration in the semiconductor layer and the well region, impurity concentration which is within a known range in this field can be used. In the case of using the SOI substrate as the semiconductor layer, the well region may be formed in the surface semiconductor layer and a body region may be provided below a channel region.

The gate insulating film is not particularly limited as long as it is usually used for a semiconductor device, and an example thereof include a single-layer film or a laminated film of an insulating film such as a silicon oxide film or a silicon nitride film, or a high dielectric constant film such as an aluminum oxide film, a titanium oxide film, a tantalum oxide film or a hafnium oxide film. Particularly, a silicon oxide film is preferable. The gate insulating film has a thickness of, for example, about 1 to 20 nm, preferably, about 1 to 6 nm. The gate insulating film may be formed only immediately below the gate electrode or formed so as to be larger (wider) than the gate electrode.

The gate electrode is formed in a shape which is usually used for a semiconductor device or a shape having a recess in a lower end portion on the gate insulating film. The gate electrode is formed preferably in an integral form without being separated by a single-layered or multilayer conductive film. The gate electrode may be disposed in a state where it is separated by a single-layered or multilayer conductive film. The gate electrode may have a side-wall insulating film on its sidewalls. Usually, the gate electrode is not particularly limited as long as it is used for a semiconductor device, and an example of thereof includes a conductive film, for example, a single-layered or multilayer film made of polysilicon, a metal such as copper or aluminum, a high-refractory metal such as tungsten, titanium or tantalum, and a silicide or the like with the high refractory metal. Suitable thickness of the gate electrode is, for example, about 50 to 400 nm. Below the gate electrode, a channel region is formed.

Preferably, the gate electrode is formed only on the sidewalls of the memory functional unit or does not cover the top part of the memory functional unit. By such arrangement, a contact plug can be disposed closer to the gate electrode, so that reduction in the size of the memory cell is facilitated. It is easy to manufacture the sidewall memory cell having such simple arrangement, so that the yield can be improved.

The memory functional unit has at least the function of retaining charges (hereinafter, described as “charge retaining function”). In other words, the memory functional unit has the function of accumulating and retaining charges, the function of trapping charges or the function of holding a charge polarization state. The function is exhibited, for example, when the memory functional unit includes a film or region having the charge retaining function. Examples of elements having the above function include: silicon nitride; silicon; a silicate glass including impurity such as phosphorus or boron; silicon carbide; alumina; a high dielectric material such as hafnium oxide, zirconium oxide or tantalum oxide; zinc oxide; ferroelectric; metals, and the like. Therefore, the memory functional unit can be formed by, for example, a single-layered or laminated structure of: an insulating film including a silicon nitride film; an insulating film having therein a conductive film or a semiconductor layer; an insulating film including at least one conductor or semiconductor dot; or an insulating film including a ferroelectric film of which inner charge is polarized by an electric field and in which the polarized state is held. Particularly, the silicon nitride film is preferable for the reason that the silicon nitride film can obtain a large hysteretic characteristic since a number of levels of trapping charges exist. In addition, the charge retention time is long and a problem of charge leakage due to occurrence of a leak path does not occur, so that the retention characteristics are good. Further, silicon nitride is a material which is used as standard in an LSI process.

By using the insulating film including a film having the charge retaining function such as a silicon nitride film as the memory functional unit, reliability of storage and retention can be increased. Since the silicon nitride film is an insulator, even in the case where a charge leak occurs in part of the silicon nitride film, the charges in the whole silicon nitride film are not lost immediately. In the case of arranging a plurality of sidewall memory cells, even when the distance between the sidewall memory cells is shortened and neighboring memory cells come into contact with each other, unlike the case where the memory functional units are made of conductors, information stored in the memory functional units is not lost. Further, a contact plug can be disposed closer to the memory functional unit. In some cases, the contact plug can be disposed so as to be overlapped with the memory functional unit. Thus, reduction in size of the memory cell is facilitated.

In order to increase the reliability of storage and retention, the film having the charge retaining function does not always have to have a film shape. Preferably, films having the charge retaining function exist discretely in an insulating film. Concretely, it is preferable that the films having the charge retaining function in the shape of dots be spread in a material which is hard to retain charges, for example, in a silicon oxide.

In the case of using a conductive film or semiconductor layer as the charge retaining film, preferably, the conductive film or semiconductor layer is disposed via an insulating film so that the charge retaining film is not in direct contact with the semiconductor layer (semiconductor substrate, well region, body region, source/drain regions or diffusion region) or a gate electrode. For example, a laminated structure of the conductive film and the insulating film, a structure in which conductive films in the form of dots are spread in the insulating film, a structure in which the conductive film is disposed in a part of a sidewall insulating film formed on sidewalls of the gate, and the like can be mentioned.

It is preferable to use the insulating film having therein the conductive film or semiconductor layer as a memory functional unit for the reason that an amount of injecting charges into the conductor or semiconductor can be freely controlled and multilevel values can be easily obtained.

Further, it is preferable to use the insulating film including at least one conductor or semiconductor dot as the memory functional unit for the reason that it becomes easier to perform writing and erasing by direct tunneling of charges, and reduction in power consumption can be achieved.

Alternatively, as a memory functional unit, a ferroelectric film such as PZT or PLZT in which the polarization direction changes according to the electric field may be used. In this case, charges are substantially generated in the surface of the ferroelectric film by the polarization and are held in that state. It is therefore preferable since the ferroelectric film can obtain a hysteresis characteristic similar to that of a film to which charges are supplied from the outside of the film having the memory function and which traps charges. In addition, it is unnecessary to inject charges from the outside of the film in order to retain charges in the ferroelectric film, and the hysteresis characteristic can be obtained only by the polarization of the charge in the film, so that writing/erasing can be performed at high speed.

As the insulating film constructing the memory functional unit, a film having a region or function of suppressing escape of charges is suitable. An example of a film having the function of suppressing escape of charges includes a silicon oxide film.

The charge retaining film included in the memory functional unit is disposed on both sides of the gate electrode directly or via an insulating film, and is disposed on the semiconductor layer (semiconductor substrate, well region, body region or source/drain region, or diffusion region) directly or via a gate insulating film. Preferably, the charge retaining film on both sides of the gate electrode is formed so as to cover all or part of the sidewalls of the gate electrode directly or via the insulating film. In an application example, in the case where the gate electrode has a recess in its lower end, the charge retaining film may be formed so as to completely or partially bury the recess directly or via an insulating film.

The diffusion regions can function as source and drain regions and have the conductive type opposite to that of the semiconductor layer or well region. In the junction between the diffusion region and the semiconductor layer or well region, preferably, impurity concentration is high for the reason that hot electrons or hot holes are generated efficiently with low voltage, and high-speed operation can be performed with lower voltage. The junction depth of the diffusion region is not particularly limited but can be appropriately adjusted in accordance with the performance or the like of a semiconductor memory device to be obtained. In the case of using an SOI substrate as a semiconductor substrate, the diffusion region may have a junction depth smaller than the thickness of the surface semiconductor layer. It is preferable that the diffusion region has junction depth almost the same as that of the surface semiconductor layer.

The diffusion region may be disposed so as to overlap with an end of the gate electrode, so as to match an end of the gate electrode, or so as to be offset from an end of the gate electrode. The case of offset is particularly preferable because easiness of inversion of the offset region below the charge retaining film largely changes in accordance with an amount of charges accumulated in the memory functional unit when voltage is applied to the gate electrode, the memory effect increases, and a short channel effect is reduced. However, when the diffusion region is offset too much, drive current between the diffusion regions (source and drain) decreases conspicuously. Therefore, it is preferable that the offset amount, that is, the distance to the diffusion area closer to one of the gate electrode ends in the gate length direction is shorter than the thickness of the charge retaining film extending in the direction parallel with the gate length direction. It is particularly important that at least a part of the film or region having the charge retaining function in the memory functional unit is overlapped with part of the diffusion region. This is because the essence of the memory cell as a component of the semiconductor memory device is to rewrite stored information by an electric field which is applied across the memory functional unit in accordance with the voltage difference between the gate electrode which exists only in the sidewall part of the memory functional unit and the diffusion region.

A part of the diffusion region may extend at a level higher than the surface of the channel region or the under face of the gate insulating film. In this case, it is suitable that, on the diffusion region formed in the semiconductor substrate, the conductive film integrated with the diffusion region is laminated. The conductive film is made of semiconductor such as polysilicon or amorphous silicon, silicide, the above-described metals, high-refractory metals, or the like. In particular, polysilicon is preferred. Since impurity diffusion speed of polysilicon is much faster than that of the semiconductor layer, it is easy to make the junction depth of the diffusion region in the semiconductor layer shallow and to suppress the short channel effect. In this case, preferably, a part of the diffusion region is disposed so as to sandwich at least a part of the memory functional unit in cooperation with the gate electrode.

The sidewall memory cell can be formed by a normal semiconductor process, for example, a method similar to the method of forming the sidewall spacer having the single-layer or laminated structure on the sidewalls of the gate electrode. Concrete examples of the method include; a method of forming the gate electrode, after that, forming a single-layer film or laminated film including the charge retaining film such as a film having the function of retaining charges (hereinafter, described as “charge retaining film”), charge retaining film/insulating film, insulating film/charge retaining film, or insulating film/charge retaining film/insulating film, and etching back the formed film under suitable conditions so as to leave the films in a sidewall spacer shape; a method of forming an insulating film or charge retaining film, etching back the film under suitable conditions so as to leave the film in the sidewall spacer shape, further forming the charge retaining film or insulating film, and similarly etching back the film so as to leave the film in the sidewall spacer shape; a method of applying or depositing an insulating film material in which particles made of a charge retaining material are spread on the semiconductor layer including the gate electrode and etching back the material under suitable conditions so as to leave the insulating film material in a sidewall spacer shape; and a method of forming a gate electrode, after that, forming the single-layer film or laminated film, and patterning the film with a mask. According to another method, before the gate electrode is formed, charge retaining film, charge retaining film/insulating film, insulating film/charge retaining film, insulating film/charge retaining film/insulating film, or the like is formed. An opening is formed in a region which becomes the channel region of the films, a gate electrode material film is formed on the entire surface of the opening, and the gate electrode material film is patterned in a shape including the opening and larger than the opening.

One example of a method for forming the sidewall memory cell according to the present invention will now be described. First, the gate insulating film and the gate electrode are formed on the semiconductor substrate in accordance with known procedures. Subsequently, a silicon oxide film having a thickness of 0.8 to 20 nm, more preferably 3 to 10 nm is formed by thermal oxidation or deposited by CVD (Chemical Vapor Deposition) over the entire semiconductor substrate. Next, a silicon nitride film having a thickness of 2 to 15 nm, more preferably 3 to 10 nm is deposited by the CVD over the entire silicon oxide film. Moreover, another silicon oxide film having a thickness of 20 to 70 nm is deposited by the CVD over the entire silicon nitride film.

Subsequently, the silicon oxide film/silicon nitride film/silicon oxide film are etched back by anisotropic etching, thereby forming the memory functional unit optimum for storing data on the sidewall of the gate electrode in the form of a sidewall spacer.

Thereafter, ions are injected while using the gate electrode and the memory functional unit in the form of the sidewall spacer as masks, thereby forming a diffusion layer region (source/drain region). After that, a silicide process or an upper wiring process may be performed in accordance with known procedures.

In the case of constructing the memory cell array by arranging sidewall memory cells, the best mode of the sidewall memory cell satisfies all of the requirements: for example, (1) the gate electrodes of a plurality of sidewall memory cells are integrated and have the function of a word line; (2) the memory functional units are formed on both sides of the word line; (3) an insulator, particularly, a silicon nitride film retains charges in the memory functional unit; (4) the memory functional unit is constructed by an ONO (Oxide Nitride Oxide) film and the silicon nitride film has a surface almost parallel with the surface of the gate insulating film; (5) a silicon nitride film in the memory functional unit is isolated from a word line and a channel region via a silicon oxide film; (6) the silicon nitride film and a diffusion region in the memory functional unit are overlapped; (7) the thickness of the insulating film separating the silicon nitride film having the surface which is almost parallel with the surface of the gate insulating film from the channel region or semiconductor layer and the thickness of the gate insulating film are different from each other; (8) an operation of writing/erasing one sidewall memory cell is performed by a single word line; (9) there is no electrode (word line) having the function of assisting the writing/erasing operation on the memory functional unit; and (10) in a portion in contact with the diffusion region immediately below the memory functional unit, a region of high concentration of impurity whose conductive type is opposite to that of the diffusion region is provided. It is sufficient for the memory cell to satisfy even one of the requirements.

A particularly preferable combination of the requirements is, for example, (3) an insulator, particularly, a silicon nitride film retains charges in the memory functional unit, (6) the insulating film (silicon nitride film) and the diffusion region in the memory functional unit are overlapped, and (9) there is no electrode (word line) having the function of assisting the writing/erasing operation on the memory functional unit.

In the case where the memory cell satisfies the requirements (3) and (9), it is very useful for the following reasons.

First, the bit line contact can be disposed closer to the memory functional unit on the word line sidewall or even when the distance between sidewall memory cells is shortened, a plurality of memory functional units do not interfere with each other, and stored information can be held. Therefore, reduction in size of the memory cell is facilitated. In the case where the charge retaining region in the memory functional unit is made of a conductor, as the distance between sidewall memory cells decreases, interference occurs between the charge retaining regions due to capacitive coupling, so that stored information cannot be held.

In the case where the charge retaining region in the memory functional unit is made of an insulator (for example, a silicon nitride film), it becomes unnecessary to make the memory functional unit independent for each sidewall memory cell. For example, the memory functional units formed on both sides of a single word line shared by a plurality of sidewall memory cells do not have to be isolated for each sidewall memory cell. The memory functional units formed on both sides of one word line can be shared by a plurality of sidewall memory cells sharing the word line. Consequently, a photo etching process for isolating the memory functional unit becomes unnecessary, and the manufacturing process is simplified. Further, a margin for positioning in the photolithography process and a margin for film reduction by etching become unnecessary, so that the margin between neighboring sidewall memory cells can be reduced. Therefore, as compared with the case where the charge retaining region in the memory functional unit is made of a conductor (for example, polysilicon film), even when the memory functional unit is formed at the same microfabrication level, a sidewall memory cell occupied area can be reduced. In the case where the charge retaining region in the memory functional unit is made of a conductor, the photo etching process for isolating the memory functional unit for each sidewall memory cell is necessary, and a margin for positioning in the photolithography process and a margin for film reduction by etching are necessary.

Moreover, since the electrode having the function of assisting the writing and erasing operations does not exist on the memory functional unit and the device structure is simple, the number of processes decreases, so that the yield can be increased. Therefore, it facilitates formation with a transistor as a component of a logic circuit or an analog circuit, and a cheap semiconductor memory device can be obtained.

The present invention is more useful in the case where not only the requirements (3) and (9) but also the requirement (6) are satisfied.

Specifically, by overlapping the charge retaining region in the memory functional unit and the diffusion region, writing and erasing can be performed with a very low voltage. Concretely, with a low voltage of 5 V or less, the writing and erasing operations can be performed. The action is a very large effect also from the viewpoint of circuit designing. Since it is unnecessary to generate a high voltage in a chip unlike a flash memory, a charge pumping circuit requiring a large occupation area can be omitted or its scale can be reduced. Particularly, when a memory of small-scale capacity is provided for adjustment in a logic LSI, as for an occupied area in a memory part, an occupation area of peripheral circuits for driving a sidewall memory cell is dominant more than that of a sidewall memory cell. Consequently, omission or down sizing of the charge pumping circuit for a sidewall memory cell is most effective to reduce the chip size.

On the other hand, in the case where the requirement (3) is not satisfied, that is, in the case where a conductor retains charges in the memory functional unit, even when the requirement (6) is not satisfied, specifically, even when the conductor in the memory functional unit and the diffusion region do not overlap with each other, writing operation can be performed. This is because that the conductor in the memory functional unit assists writing operation by capacitive coupling with the gate electrode.

In the case where the requirement (9) is not satisfied, specifically, in the case where the electrode having the function of assisting the writing and erasing operations exists on the memory functional unit, even when the requirement (6) is not satisfied, specifically, even when the insulator in the memory functional unit and the diffusion region do not overlap with each other, writing operation can be performed.

In the semiconductor memory device of the present invention, a transistor may be connected in series with one of or both sides of a sidewall memory cell, or the sidewall memory cell may be mounted on the same chip with a logic transistor. In such a case, the semiconductor device of the present invention, particularly, the sidewall memory cell can be formed by a process having high compatibility with a process of forming a normal standard transistor such as a transistor or a logic transistor, they can be formed simultaneously. Therefore, a process of forming both the sidewall memory cell and a transistor or a logic transistor is very simple and, as a result, a cheap embedded device can be obtained.

In the semiconductor memory device of the present invention, the sidewall memory cell can store information of two or more values in one memory functional unit. Thus, the sidewall memory cell can function as a memory cell for storing information of four or more values. The sidewall memory cell may store binary data only. The sidewall memory cell is also allowed to function as a memory cell having the functions of both a selection transistor and a memory transistor by a variable resistance effect of the memory functional unit.

The semiconductor memory device of the present invention can be widely applied by being combined with a logic device, a logic circuit or the like to: a data processing system such as a personal computer, a note-sized computer, a laptop computer, a personal assistant/transmitter, a mini computer, a workstation, a main frame, a multiprocessor/computer, a computer system of any other type, or the like; an electronic part as a component of the data processing system, such as a CPU, a memory or a data memory device; a communication apparatus such as a telephone, a PHS, a modem or a router; an image display apparatus such as a display panel or a projector; an office apparatus such as a printer, a scanner or a copier; an image pickup apparatus such as a video camera or a digital camera; an entertainment apparatus such as a game machine or a music player; an information apparatus such as a portable information terminal, a watch or an electronic dictionary; a vehicle-mounted apparatus such as a car navigation system or a car audio system; an AV apparatus for recording/reproducing information such as a motion picture, a still picture or music; an appliance such as a washing machine, a microwave, a refrigerator, a rice cooker, a dish washer, a vacuum cleaner or an air conditioner; a health managing apparatus such as a massage device, a bathroom scale or a manometer; and a portable memory device such as an IC card or a memory card. Particularly, it is effective to apply the semiconductor memory device to portable electronic apparatuses such as portable telephone, portable information terminal, IC card, memory card, portable computer, portable game machine, digital camera, portable motion picture player, portable music player, electronic dictionary and watch. The semiconductor memory device of the present invention may be provided as at least a part of a control circuit or a data storing circuit of an electronic device or, as necessary, detachably assembled.

### DESCRIPTION OF THE PREFERRED EMBODIMENTS

Hereinafter, embodiments of the semiconductor memory device and the portable electronic apparatus of the present invention will be described in detail with reference to the drawings.

First Embodiment

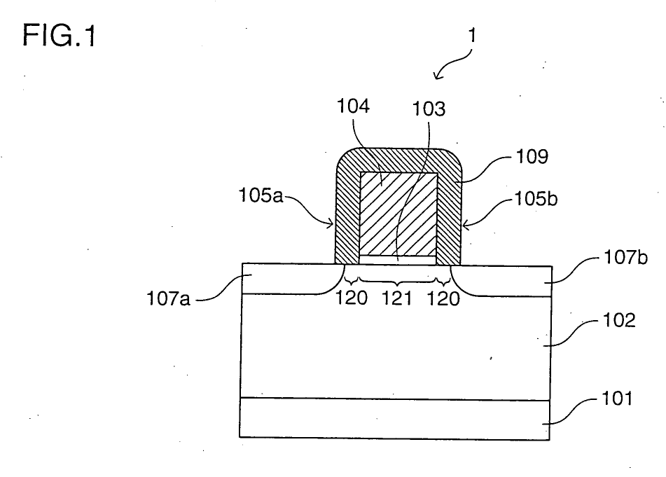

A semiconductor memory device of a first embodiment has a sidewall memory cell 1 as shown in FIG. 1.

The sidewall memory cell 1 has a gate electrode 104 formed on a P-type well region 102 formed on the surface of a semiconductor substrate 101 via a gate insulating film 103. On the top face and side faces of the gate electrode 104, a silicon nitride film 109 having a trap level of retaining charges and serving as a charge retaining film is disposed. In the silicon nitride film 109, parts of both sidewalls of the gate electrode 104 serve as memory functional units 105a and 105b for actually retaining charges. The memory functional unit refers to a part in which charges are actually accumulated by rewriting operation in the memory functional unit or the charge retaining film. In the P-type well region 102 on both sides of the gate electrode 104, N-type diffusion regions 107a and 107b functioning as a source region and a drain region, respectively, are formed. Each of the diffusion regions 107a and 107b has an offset structure. Specifically, the diffusion regions 107a and 107b do not reach a region 121 below the gate electrode 104, and offset regions 120 below the charge retaining film construct part of the channel region.

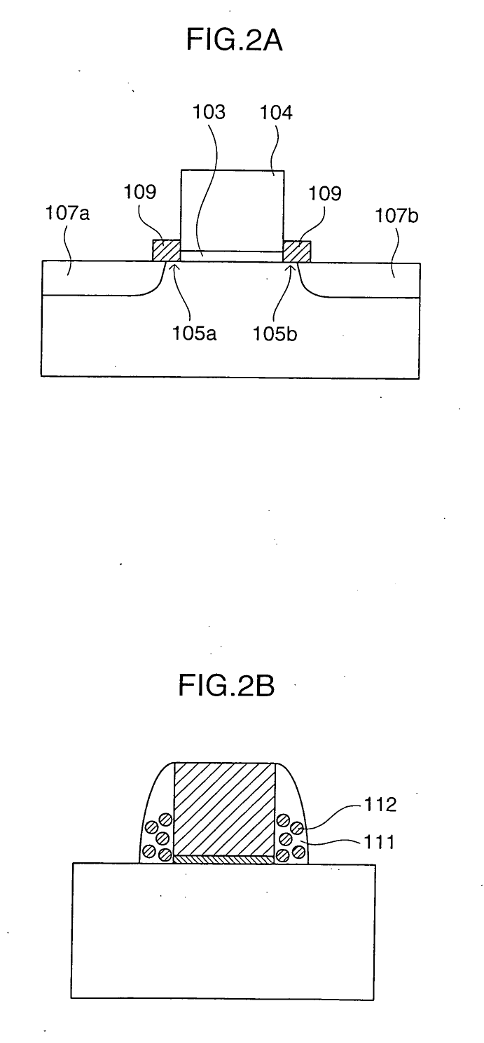

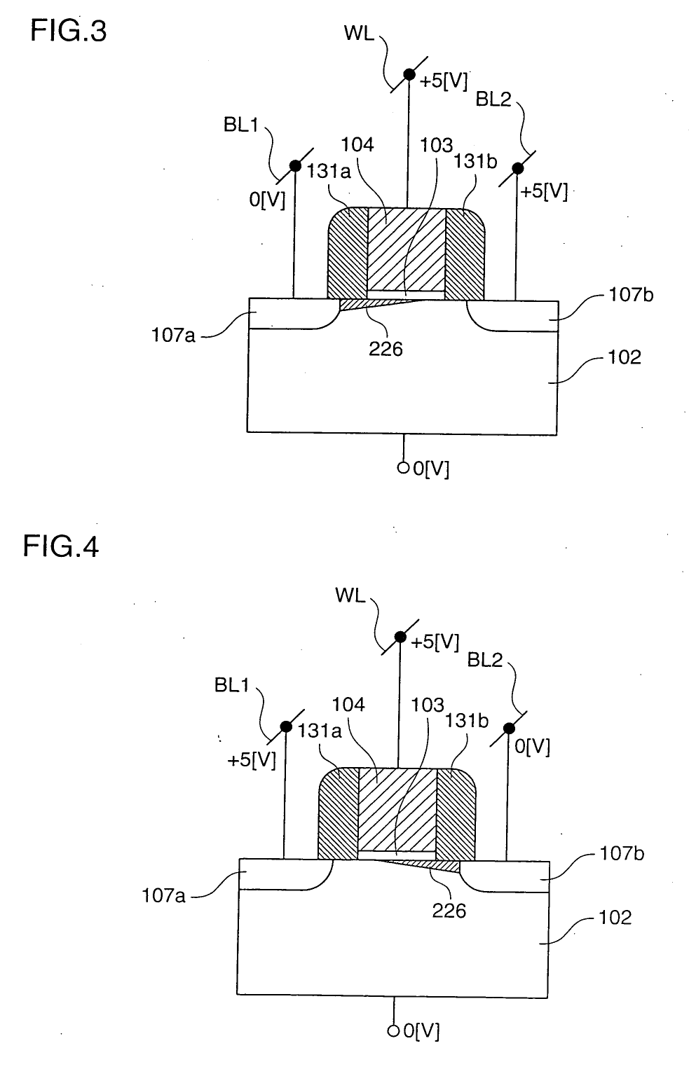

The memory functional units 105a and 105b for substantially retaining charges are the parts on both sidewalls of the gate electrode 104. It is therefore sufficient that the silicon nitride film 109 is formed only in regions corresponding to the parts (see FIG. 2A). Each of the memory functional units 105a and 105b may have a structure in which fine particles 111 each made of a conductor or semiconductor and having a nanometer size are distributed like discrete points in an insulating film 112 (see FIG. 2B). When the fine particle 111 has a size less than 1 nm, a quantum effect is too large, so that it becomes hard for charges to go through the dots. When the size exceeds 10 nm, a conspicuous quantum effect does not appear at room temperature. Therefore, the diameter of the fine particle 111 is preferably in a range from 1 nm to 10 nm. The silicon nitride film 109 serving as a charge retaining film may be formed in a sidewall spacer shape on a side face of the gate electrode (see FIG. 3).

The principle of the writing operation of the sidewall memory cell will be described with reference to FIGS. 3 and 4. The case where whole memory functional units 131a and 131b have the function of retaining charges will be described. “Writing” denotes herein injection of electrons into the memory functional units 131a and 131b when the sidewall memory cell is of the N channel type. Hereinafter, on assumption that sidewall the memory cell is of the N channel type, description will be given.

In order to inject electrons (write) the second memory functional unit 131b, as shown in FIG. 3, the first diffusion region 107a of the N type is set as a source electrode, and the second diffusion region 107b of the N type is set as a drain electrode. For example, 0 V is applied to the first diffusion region 107a and the P-type well region 102, +5 V is applied to the second diffusion region 107b, and +5 V is applied to the gate electrode 104. Under such voltage parameters, an inversion layer 226 extends from the first diffusion region 107a (source electrode) but does not reach the second diffusion region 107b (drain electrode), and a pinch off point occurs. Electrons are accelerated from the pinch-off point to the second diffusion region 107b (drain electrode) by a high electric field, and become so-called hot electrons (high-energy conduction electrons). By injection of the hot electrons into the second memory functional unit 131b, writing is performed. Since hot electrons are not generated in the vicinity of the first memory functional unit 131a, writing is not performed.

On the other hand, in order to inject electrons (write) into the first memory functional unit 131a, as shown in FIG. 4, the second diffusion region 107a is set as the source electrode, and the first diffusion region 107a is set as the drain electrode. For example, 0 V is applied to the second diffusion region 107b and the P-type well region 102, +5 V is applied to the first diffusion region 107a, and +5 V is applied to the gate electrode 104. By interchanging the source and drain regions so as to be different from the case of injecting electrons into the second memory functional unit 131b, electrons are injected into the first memory functional unit 131a and writing can be performed.

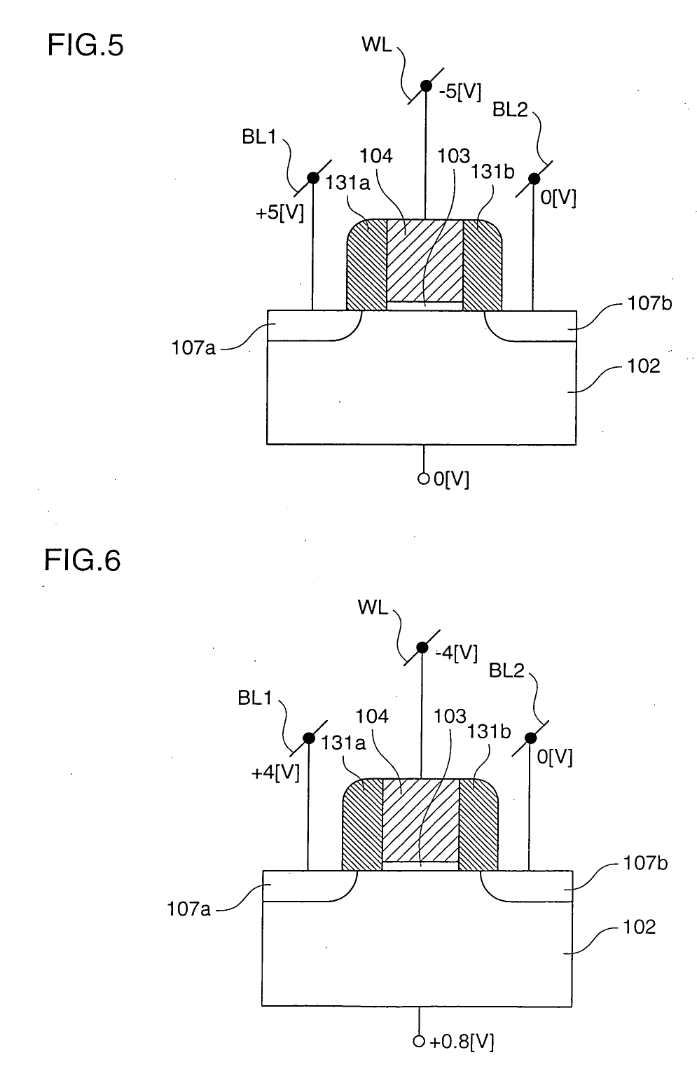

The principle of erasing operation of the sidewall memory cell will now be described with reference to FIGS. 5 and 6.

In a first method of erasing information stored in the first memory functional unit 131a, by applying positive voltage (for example, +5 V) to the first diffusion region 107a and applying 0 V to the P-type well region 102 as shown in FIG. 5, the PN junction between the first diffusion region 107a and the P-type well region 102 is reverse-biased and, further, negative voltage (for example, −5 V) is applied to the gate electrode 104. At this time, in the vicinity of the gate electrode 104 in the PN junction, due to the influence of the gate electrode to which the negative voltage is applied, particularly, gradient of potential becomes sharp. Consequently, hot holes (positive holes of high energy) are generated on the side of the P-type well region 102 of the PN junction by interband tunneling. The hot holes are attracted toward the gate electrode 104 having a negative potential and, as a result, the holes are injected to the first memory functional unit 131a. In such a manner, information in the first memory functional unit 131a is erased. At this time, to the second diffusion region 107b, it is sufficient to apply 0 V.

In the case of erasing information stored in the second memory functional unit 131b, the above-described operation is performed while interchanging the potential of the first diffusion region and that of the second diffusion region.

In a second method of erasing information stored in the first memory functional unit 131a, as shown in FIG. 6, positive voltage (for example, +4 V) is applied to the first diffusion region 107a, 0 V is applied to the second diffusion region 107b, negative voltage (for example, −4 V) is applied to the gate electrode 104, and positive voltage (for example, +0.8 V) is applied to the P-type well region 102. At this time, forward voltage is applied between the P-type well region 102 and the second diffusion region 107b, and electrons are injected to the P-type well region 102. The injected electrons are diffused to the PN junction between the P-type well region 102 and the first diffusion region 107a, where the electrons are accelerated by a strong electric field, thereby becoming hot electrons. By the hot electrons, an electron-hole pair is generated in the PN junction. Specifically, by applying forward voltage between the P-type well region 102 and the second diffusion region 107b, electrons injected in the P-type well region 102 become a trigger, and hot holes are generated in the PN junction positioned on the opposite side. The hot holes generated in the PN junction are attracted toward the gate electrode 104 having the negative potential and, as a result, positive holes are injected into the first memory functional unit 131a.

According to the method, also in the case where only voltage insufficient to generate hot holes by interband tunneling is applied to the PN junction between the P-type well region and the first diffusion region 107a, electrons injected from the second diffusion region 107b become a trigger to generate an electron-positive hole pair in the PN junction, thereby enabling hot holes to be generated. Therefore, voltage in the erasing operation can be decreased. Particularly, in the case where the offset region 120 (see FIG. 1) exists, an effect that the gradient of potential in the PN junction becomes sharp by the gate electrode to which the negative potential is applied is low. Consequently, although it is difficult to generate hot holes by interband tunneling, by the second method, the disadvantage is overcome and the erasing operation can realized with low voltage.

In the case of erasing information stored in the first memory functional unit 131a, +5 V has to be applied to the first diffusion region 107a in the first erasing method whereas +4 V is sufficient in the second erasing method. As described above, according to the second method, the voltage at the time of erasing can be decreased, so that power consumption can be reduced and deterioration of the memory cell due to hot carriers can be suppressed.

In any of the erasing methods, over-erasure does not occur easily in the memory cell. The over-erasure herein denotes a phenomenon that as the amount of positive holes accumulated in the memory functional unit increases, the threshold decreases without saturation. The over-erasure is a big issue in an EEPROM typified by a flash memory. Particularly, in the case where the threshold becomes negative, critical malfunctioning that selection of a memory cell becomes impossible occurs. On the other hand, in the memory cell in the semiconductor memory device of the present invention, also in the case where a large amount of positive holes are accumulated in the memory functional unit, only electrons are induced below the memory functional unit but an influence is hardly exerted to the potential in the channel region below the gate insulating film. Since the threshold at the time of erasing is determined by the potential below the gate insulating film, occurrence of over-erasure is suppressed.

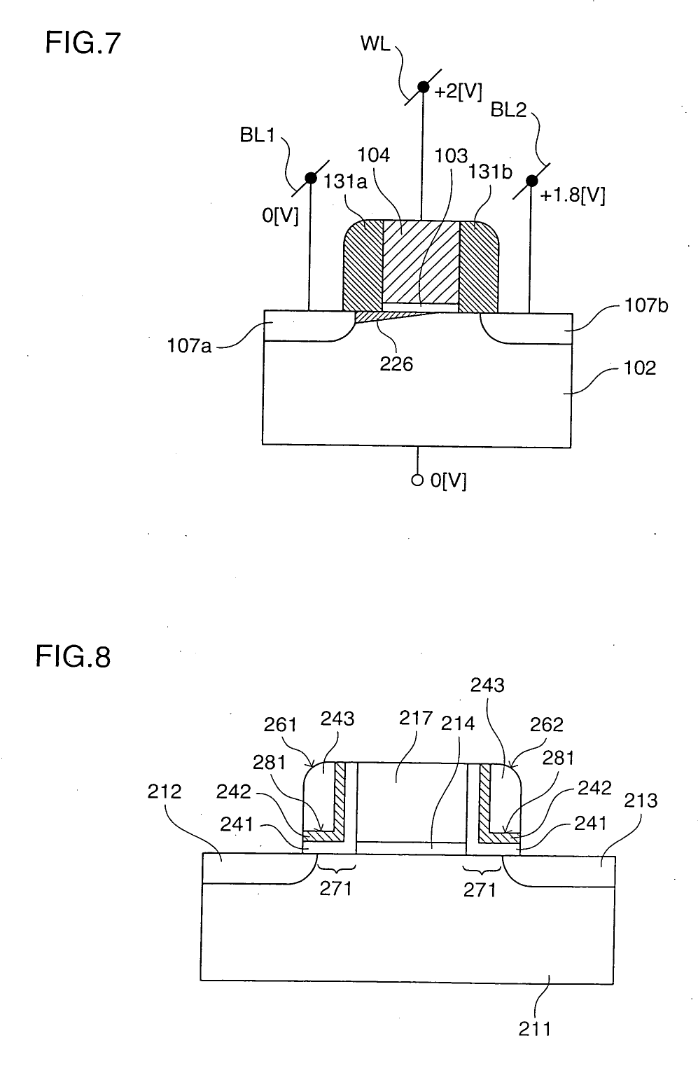

Further, the principle of reading operation of the sidewall memory cell will be described with reference to FIG. 7.

In the case of reading information stored in the first memory functional unit 131a, the first diffusion region 107a is set as a source electrode, the second diffusion region 107b is set as a drain electrode, and the transistor is allowed to operate in a saturated region. For example, 0 V is applied to the first diffusion region 107a and the P-type well region 102, +1.8 V is applied to the second diffusion region 107b, and +2 V is applied to the gate electrode 104. In the case where electrons are not accumulated in the first memory functional unit 131a at this time, drain current is apt to flow. On the other hand, in the case where electrons are accumulated in the first memory functional unit 131a, an inversion layer is not easily formed in the vicinity of the first memory functional unit 131a, so that the drain current is not apt to flow. Therefore, by detecting the drain current, information stored in the first memory functional unit 131a can be read. In the case of applying a voltage so as to perform the pinch-off operation, thereby reading information, it is possible to determine with higher accuracy the state of charge accumulation in the first memory functional unit 131a without influence of the presence/absence of charge accumulation in the second memory functional unit 131b.

In the case of reading information stored in the second memory functional unit 131b, the second diffusion region 107b is set as a source electrode, the first diffusion region 107a is set as a drain electrode, and the transistor is operated. It is sufficient to apply, for example, 0V to the second diffusion region 107b and the P-type well region 102, +1.8 V to the first diffusion region 107a, and +2 V to the gate electrode 104. By interchanging the source and drain regions of the case of reading information stored in the first memory functional unit 131a, information stored in the second memory functional unit 131b can be read.

In the case where a channel region (offset region 120) which is not covered with the gate electrode 104 remains, in the channel region which is not covered with the gate electrode 104, an inversion layer is dissipated or formed according to the presence/absence of excessive charges in the memory functional units 131a and 131b and, as a result, large hysteresis (change in the threshold) is obtained. However, when the offset region 120 is too wide, the drain current largely decreases and reading speed becomes much slower. Therefore, it is preferable to determine the width of the offset region 120 so as to obtain sufficient hysteresis and reading speed.

Also in the case where the diffusion regions 107a and 107b reach ends of the gate electrode 104, that is, the diffusion regions 107a and 107b overlap with the gate electrode 104, the threshold of the transistor hardly changes by the writing operation. However, parasitic resistance at the source/drain ends largely changes, and the drain current largely decreases (by equal to or more than one digit). Therefore, reading can be performed by detecting the drain current, and the function as a memory can be obtained. In the case where a larger memory hysteresis effect is necessary, it is preferable that the diffusion regions 107a and 107b and the gate electrode 104 are not overlapped (offset region 120 exists).

By the above operating method, two bits can be written/erased selectively per one transistor. By connecting a word line WL to the gate electrode 104 of the sidewall memory cell, connecting a first bit line BL1 to the first diffusion region 107a, connecting a second bit line BL2 to the second diffusion region 107b, and arranging sidewall memory cells, a sidewall memory cell array can be constructed.

In the above-described operating method, by interchanging the source electrode and the drain electrode, writing and erasing of two bits per one transistor are performed. Alternately, by fixing the source electrode and the drain electrode, the transistor may operate as a 1-bit memory. In this case, common fixed voltage can be applied to one of the source and drain regions, so that the number of bit lines connected to the source/drain regions can be reduced to the half.

As obvious from the above description, in the sidewall memory cell in the semiconductor memory device of the present invention, the memory functional unit is formed independently of the gate insulating film, and is formed on both sides of the gate electrode, so that 2-bit operation is possible. Since each memory functional unit is isolated by the gate electrode, interference at the time of rewriting is effectively suppressed. Further, since the gate insulating film is isolated from the memory functional unit, it can be formed thinly and a short channel effect can be suppressed. Therefore, reduction in size of the memory cell and, accordingly, the semiconductor memory device can be achieved easily.

Second Embodiment

A sidewall memory cell in a semiconductor memory device according to a second embodiment has a configuration substantially similar to that of the sidewall memory cell 1 of FIG. 1 except that, as shown in FIG. 8, each of memory functional units 261 and 262 is constructed by a charge retaining region (which is a charge accumulating region and may be a film having the function of retaining charges) and a region for suppressing escape of charges (or a film having the function of suppressing escape of charges).

From the viewpoint of improving a memory retention characteristic, preferably, the memory functional unit includes a charge retaining film having the function of retaining charges and an insulating film. In the second embodiment, a silicon nitride film 242 having a level of trapping charges is used as the charge retaining film, and silicon oxide films 241 and 243 having the function of preventing dissipation of charges accumulated in the charge retaining are used as insulating films. The memory functional unit includes the charge retaining film and the insulating films, thereby preventing dissipation of charges, and the retention characteristic can be improved. As compared with the case where the memory functional unit is constructed only by the charge retaining film, the volume of the charge retaining film can be appropriately reduced, movement of charges in the charge retaining film is regulated, and occurrence of a characteristic change due to charge movement during retention of information can be suppressed. Further, by employing the structure in which the silicon nitride film 242 is sandwiched by the silicon oxide films 241 and 243, charge injecting efficiency at the time of rewriting operation becomes high, so that higher-speed operation can be performed. In the memory cell, the silicon nitride film 242 may be replaced with a ferroelectric.

The regions for retaining charges (silicon nitride films 242) in the memory functional units 261 and 262 overlap with diffusion regions 212 and 213. The overlap denotes herein that at least a part of the region for retaining charges (silicon nitride film 242) exists over at least a part of the diffusion regions 212 and 213. A reference numeral 211 denotes a semiconductor substrate, a reference numeral 214 denotes a gate insulating film, a reference numeral 217 denotes a gate electrode, and a reference numeral 271 indicates an offset region between the gate electrode 217 and the diffusion regions 212 and 213. Although not shown, the surface of the semiconductor substrate 211 under the gate insulating film 214 serves as a channel region.

An effect obtained when the silicon nitride films 242 as regions for retaining charges in the memory functional units 261 and 262 overlap with the diffusion regions 212 and 213 will be described.

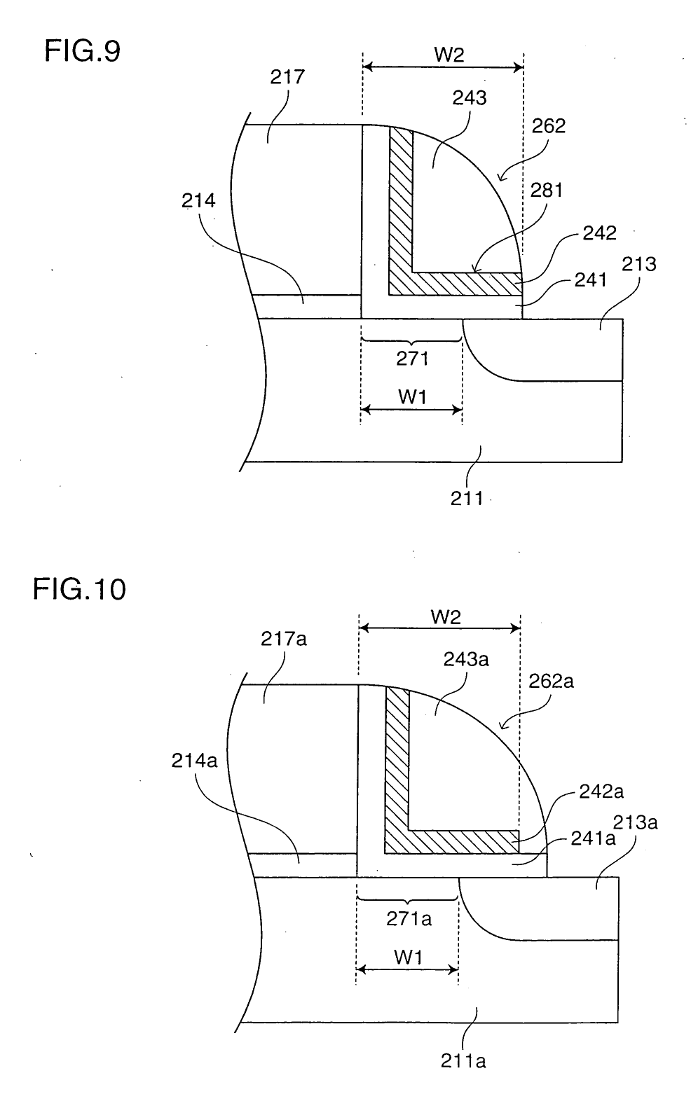

As shown in FIG. 9, in an area around the memory functional unit 262, when an offset amount between the gate electrode 217 and the diffusion region 213 is W1 and the width of the memory functional unit 262 in a cross section in the channel length direction of the gate electrode is W2, the overlap amount between the memory functional unit 262 and the diffusion region 213 is expressed as W2 -W1. It is important herein that the memory functional unit 262 constructed by the silicon oxide film 242 in the memory functional unit 262 overlaps with the diffusion region 213, that is, the relation of W2>W1 is satisfied.

In FIG. 9, an end on the side apart from the gate electrode 217 of the silicon nitride film 242 in the memory functional unit 262 matches with the end of the memory functional unit 262 on the side apart from the gate electrode 217, so that the width of the memory functional unit 262 is defined as W2.

As shown in FIG. 10, when the end on the side apart from the gate electrode of a silicon nitride film 242a in a memory functional unit 262a does not match with the end of the memory functional unit 262a on the side apart from the gate electrode, W2 may be defined as a distance from the gate electrode end to an end on the side apart from the gate electrode of the silicon nitride film 242a.

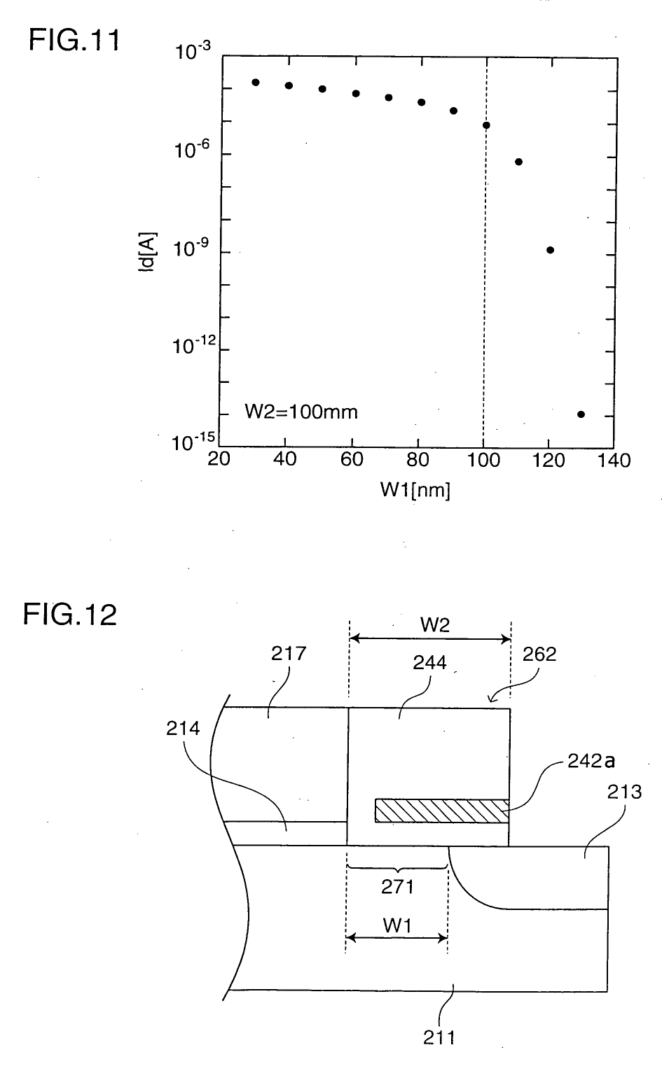

FIG. 11 shows drain current Id when the width W2 of the memory functional unit 262 is fixed to 100 nm and the offset amount W1 is changed in the structure of the sidewall memory cell of FIG. 9. Herein, the drain current was obtained by device simulation on assumption that the memory functional unit 262 is in erasing state (holes are accumulated), and the diffusion regions 212 and 213 serve as the source electrode and the drain electrode, respectively.

As obvious from FIG. 11, in the range where W1 is 100 nm or more (that is, the silicon nitride film 242 and the diffusion region 213 do not overlap with each other), the drain current sharply decreases. Since the drain current value is almost proportional to the reading operation speed, the performance of the memory sharply deteriorates with W1 of 100 nm or more. On the other hand, in the range where the silicon nitride film 242 and the diffusion region 213 overlap with each other, decrease in the drain current is gentle. Therefore, in the case of considering also variations in mass production, if at least a part of the silicon nitride film 242 as the film having the function of retaining charges does not overlap with the source and drain regions, it is difficult to obtain the memory function in reality.

On the basis of the result of the device simulation, by fixing W2 to 100 nm and setting W1 to 60 nm and 100 nm as design values, sidewall memory cell arrays were produced. In the case where W1 is 60 nm, the silicon nitride film 242 and the diffusion regions 212 and 213 overlap with each other by 40 nm as a design value. In the case where W1 is 100 nm, there is no overlap as a design value. Reading time of the sidewall memory cell arrays was measured and worst cases considering variations were compared with each other. In the where W1 is set to 60 nm as a design value, read access time is 100 times as fast as that of the other case. In practice, the read access time is preferably 100 n/sec or less per one bit. When W1=W2, the condition cannot be achieved. In the case of considering manufacture variations as well, it is more preferable that (W2−W1)>10 nm.

To read information stored in the memory functional unit 261 (region 281), in a manner similar to the first embodiment, it is preferable to set the diffusion region 212 as a source electrode, set the diffusion region 213 as a drain region, and form a pinch-off point on the side closer to the drain region in the channel region. Specifically, at the time of reading information stored in one of the two memory functional units, it is preferable to form the pinch-off point in a region closer to the other memory functional unit, in the channel region. With the arrangement, irrespective of a storage state of the memory functional unit 262, information stored in the memory functional unit 261 can be detected with high sensitivity, and it is a large factor to achieve 2-bit operation.

On the other hand, in the case of storing information only one of two memory functional units or in the case of using the two memory functional units in the same storage state, it is not always necessary to form the pinch-off point at the time of reading.

Although not shown in FIG. 8, it is preferable to form a well region (P-type well in the case of the N channel device) in the surface of the semiconductor substrate 211. By forming the well region, it becomes easy to control the other electric characteristics (withstand voltage, junction capacitance and short-channel effect) while setting the impurity concentration in the channel region optimum to the memory operations (rewriting operation and reading operation).

The memory functional unit preferably includes the charge retaining film disposed almost in parallel with the gate insulating film surface. In other words, it is preferable that the level of the top face of the charge retaining film in the memory functional unit is positioned parallel to the level of the top face of the gate insulating film 214. Concretely, as shown in FIG. 12, the silicon nitride film 242a as a charge retaining film of the memory functional unit 262 has a surface almost parallel with the surface of the gate insulating film 214. In other words, it is preferable that the silicon nitride film 242a is formed at a level parallel to the level corresponding to the surface of the gate insulating film 214.

By the existence of the silicon nitride film 242a almost parallel to the surface of the gate insulating film 214 in the memory functional unit 262, formation easiness of the inversion layer in the offset region 271 can be effectively controlled in accordance with an amount of charges accumulated in the silicon nitride film 242a. Thus, the memory effect can be increased. By forming the silicon nitride film 242a almost in parallel with the surface of the gate insulating film 214, even in the case where the offset amount (W1) varies, a change in the memory effect can be maintained relatively small, and variations of the memory effect can be suppressed. Moreover, movement of the charges upward in the silicon nitride film 242a is suppressed, and occurrence of a characteristic change due to the charge movement during retention of information can be suppressed.

Preferably, the memory functional unit 262 includes an insulating film (for example, portion on the offset region 271 in the silicon oxide film 244) for separating the silicon nitride film 242a which is almost parallel to the surface of the gate insulating film 214 and the channel region (or well region). By the insulating film, dissipation of the charges accumulated in the charge retaining film is suppressed and a sidewall memory cell having a better retention characteristic can be obtained.

By controlling the thickness of the silicon nitride film 242a and controlling the thickness of the insulating film below the silicon nitride film 242a (portion on the offset region 271 in the silicon oxide film 244) to be constant, the distance from the surface of the semiconductor substrate to charges accumulated in the charge retaining film can be maintained almost constant. To be specific, the distance from the surface of the semiconductor substrate to the charges accumulated in the charge retaining film can be controlled in a range from the minimum thickness value of the insulating film under the silicon nitride film 242a to the sum of the maximum thickness value of the insulating film under the silicon nitride film 242a and the maximum thickness value of the silicon nitride film 242a. Consequently, density of electric lines of force generated by the charges accumulated in the silicon nitride film 242a can be almost controlled, and variations in the memory effect of the sidewall memory cell can be reduced very much.

Third Embodiment

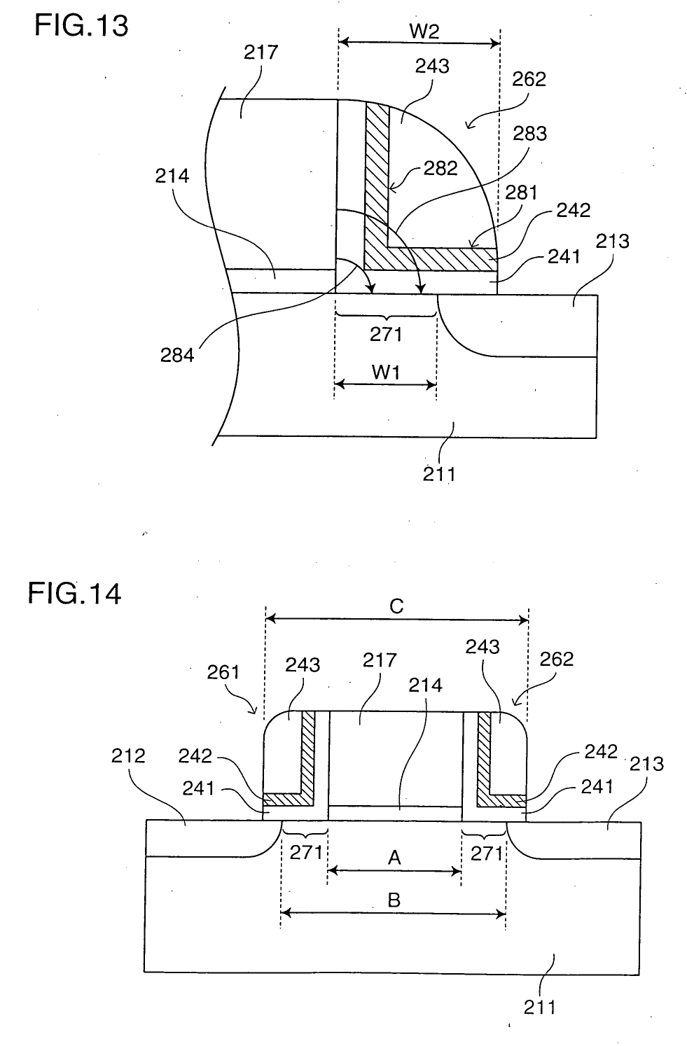

The memory functional unit 262 in a semiconductor memory device of a third embodiment has a shape in which the silicon nitride film 242 as a charge retaining film has almost uniform thickness and is disposed almost in parallel with the surface of the gate insulating film 214 as shown in FIG. 13 (region 281) and, further, almost in parallel with a side face of the gate electrode 217 (region 282).

In the case where positive voltage is applied to the gate electrode 217, an electric line 283 of force in the memory functional unit 262 passes the silicon nitride film 242 twice (regions 282 and 281) as shown by an arrow. When negative voltage is applied to the gate electrode 217, the direction of the electric line of force becomes opposite. Herein, the dielectric constant of the silicon nitride film 242 is about 6, and that of silicon oxide films 241 and 243 is about 4. Therefore, effective dielectric constant of the memory functional unit 262 in the direction of the electric line 283 of force is higher and the potential difference at both ends of the electric line of force can be reduced more as compared with the case where only the region 281 of the charge retaining film exists. In other words, a large part of the voltage applied to the gate electrode 217 is used to enhance the electric field in the offset region 271.

The reason why charges are injected to the silicon nitride film 242 in the rewriting operation is because generated charges are attracted by the electric field in the offset region 271. Therefore, by including the charge retaining film shown by the arrow 282, charges injected into the memory functional unit 262 increase in the rewriting operation, and the rewriting speed increases.

In the case where the portion of the silicon oxide film 243 is also the silicon nitride film, that is, in the case where the level of the charge retaining film is not parallel with the level corresponding to the surface of the gate insulating film 214, upward movement of charges in the silicon nitride film becomes conspicuous, and the retention characteristic deteriorates.

More preferably, in place of the silicon nitride film, the charge retaining film is made of a high dielectric such as hafnium oxide having a very high dielectric constant.

It is preferable that the memory functional unit further includes an insulating film (portion on the offset region 271 in the silicon oxide film 241) for separating the charge retaining film almost parallel to the surface of the gate insulating film and the channel region (or well region). By the insulating film, dissipation of charges accumulated in the charge retaining film is suppressed, and the retention characteristic can be further improved.

Preferably, the memory functional unit further includes an insulating film (portion in contact with the gate electrode 217 in the silicon oxide film 241) for separating the gate electrode and the charge retaining film extended almost parallel with the side face of the gate electrode. The insulating film prevents injection of charges from the gate electrode into the charge retaining film and accordingly prevents a change in the electric characteristics. Thus, the reliability of the sidewall memory cell can be improved.

Further, in a manner similar to the second embodiment, it is preferable to control the thickness of the insulating film under the silicon nitride film 242 (portion on the offset region 271 in the silicon oxide film 241) to be constant and to control the thickness of the insulating film on the side face of the gate electrode (portion in contact with the gate electrode 217 in the silicon oxide film 241) to be constant. Consequently, the density of the electric lines of force generated by the charges accumulated in the silicon nitride film 242 can be almost controlled, and charge leak can be prevented.

Fourth Embodiment

In a fourth embodiment, optimization of the gate electrode, the memory functional unit, and the distance between the source and drain regions of a sidewall memory cell in a semiconductor memory device will be described.

As shown in FIG. 14, a reference character A denotes length of the gate electrode in a cut surface in the channel length direction, a reference character B denotes the distance between the source and drain regions (channel length), and a reference character C denotes the distance from the end of one of memory functional units to the end of the other memory functional unit, that is, the distance between the end (on the side far from the gate electrode) of a film having the function of retaining charges in one of memory functional units to the end (on the side apart from the gate electrode) of a film having the function of retaining charges in the other memory functional unit in a cut surface in the channel length direction.

In such a sidewall memory cell, B<C is preferable. By satisfying such a relation, the offset regions 271 exist between the portion under the gate electrode 217 in the channel region and the diffusion regions 212 and 213. Consequently, easiness of inversion effectively fluctuates in the whole offset regions 271 by charges accumulated in the memory functional units 261 and 262 (silicon nitride films 242). Therefore, the memory effect increases and, particularly, higher-speed reading operation is realized.

In the case where the gate electrode 217 and the diffusion regions 212 and 213 are offset from each other, that is, in the case where the relation of A<B is satisfied, easiness of inversion in the offset region when voltage is applied to the gate electrode largely varies according to an amount of charges accumulated in the memory functional unit, so that the memory effect increases, and the short channel effect can be reduced.

However, as long as the memory effect appears, the offset region 271 does not always have to exist. Also in the case where the offset region 271 does not exist, if the impurity concentration in the diffusion regions 212 and 213 is sufficiently low, the memory effect can be exhibited in the memory functional units 261 and 262 (silicon nitride films 242).

Therefore, A<B<C is the most preferable.

Fifth Embodiment

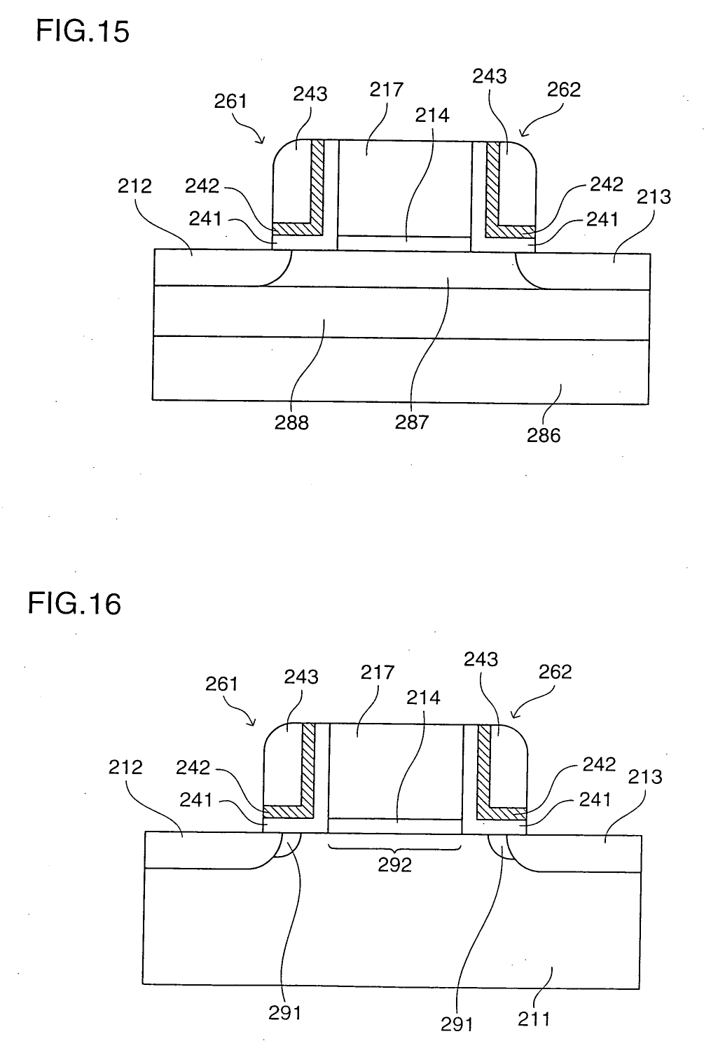

A sidewall memory cell of a semiconductor memory device in a fifth embodiment has a substantially similar configuration to that of the second embodiment except that an SOI substrate is used as the semiconductor substrate in the second embodiment as shown in FIG. 15.

In the sidewall memory cell, a buried oxide film 288 is formed on a semiconductor substrate 286, and an SOI layer is formed on the buried oxide film 288. In the SOI layer, the diffusion regions 212 and 213 are formed and the other region is a body region 287.

By the sidewall memory cell as well, action and effect similar to those of the sidewall memory cell of the second embodiment are obtained. Further, junction capacitance between the diffusion regions 212 and 213 and the body region 287 can be remarkably reduced, so that higher-speed operation and lower power consumption of the device can be achieved.

Sixth Embodiment

A sidewall memory cell in a semiconductor memory device in a sixth embodiment has, as shown in FIG. 16, a configuration substantially similar to that of the sidewall memory cell of the second embodiment except that a P-type high-concentration region 291 is added adjacent to the channel sides of the N-type diffusion regions 212 and 213.

Specifically, the concentration of a P-type impurity (for example, boron) in the P-type high-concentration region 291 is higher than that of a P-type impurity in a region 292. Suitable P-type impurity concentration in the P-type high-concentration region 291 is, for example, about 5×10¹⁷ to 1×10¹⁹ cm⁻³. The P-type impurity concentration of the region 292 can be set to, for example, 5×10¹⁶ to 1×10¹⁸ cm⁻³.

By providing the P-type high-concentration region 291, the junction between the diffusion regions 212 and 213 and the semiconductor substrate 211 becomes sharp below the memory functional units 261 and 262. Consequently, hot carriers are easily generated in the writing and erasing operations, the voltage of the writing and erasing operations can be decreased or the writing operation and the erasing operation can be performed at high speed. Moreover, since the impurity concentration in the region 292 is relatively low, the threshold when the memory is in the erasing state is low, and the drain current is large. Consequently, the reading speed is improved. Therefore, the sidewall memory cell with low rewriting voltage or high rewriting speed and high reading speed can be obtained.

In FIG. 16, by providing the P-type high-concentration region 291 in the vicinity of the source/drain regions and below the memory functional unit (that is, not immediately below the gate electrode), the threshold of the whole transistor remarkably increases. The degree of increase is much higher than that in the case where the P-type high-concentration region 291 is positioned immediately below the gate electrode. In the case where write charges (electrons when the transistor is of the N-channel type) are accumulated in the memory functional unit, the difference becomes larger. On the other hand, in the case where sufficient erasing charges (positive holes when the transistor is of the N-channel type) are accumulated in the memory functional unit, the threshold of the whole transistor decreases to a threshold determined by the impurity concentration in the channel region (region 292) below the gate electrode. That is, the threshold in the erasing operation does not depend on the impurity concentration of the P-type high-concentration region 291 whereas the threshold in the writing operation is largely influenced. Therefore, by disposing the P-type high-concentration region 291 under the memory functional unit and in the vicinity of the source/drain regions, only the threshold in the writing operation largely fluctuates, and the memory effect (the difference between the threshold in the writing operation and that in the erasing operation) can be remarkably increased.

Seventh Embodiment

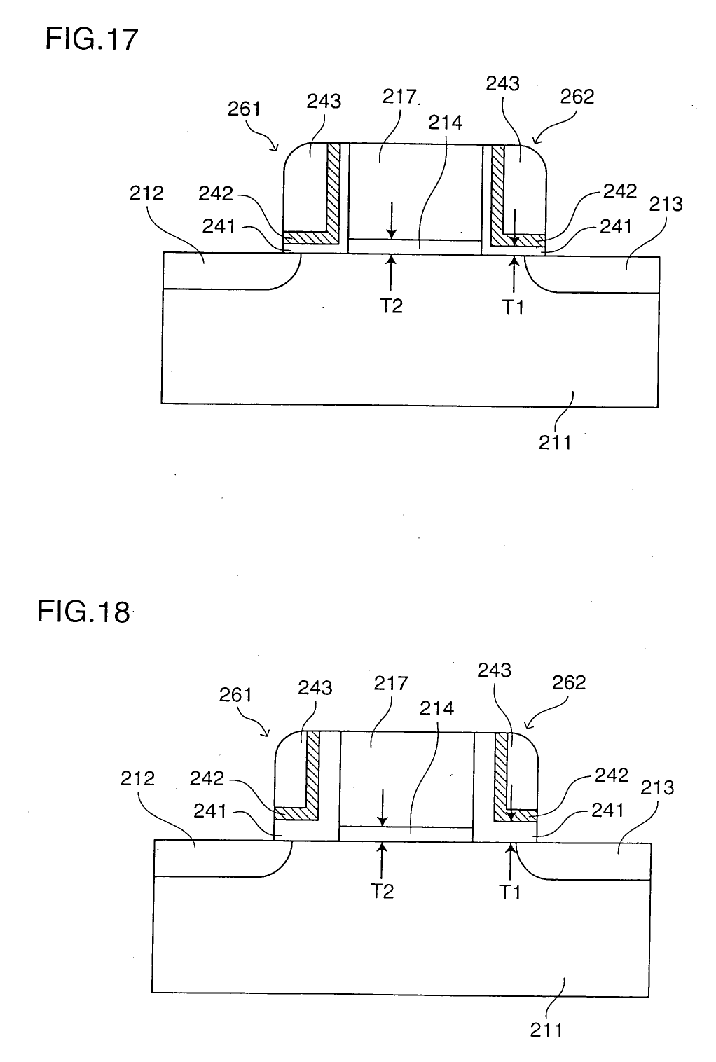

A sidewall memory cell in a semiconductor memory device of a seventh embodiment has a configuration substantially similar to that of the second embodiment except that, as shown in FIG. 17, the thickness (T1) of an insulating film separating the charge retaining film (silicon nitride film 242) and the channel region or well region is smaller than the thickness (T2) of the gate insulating film.

The thickness T2 of the gate insulating film 214 has the lower limit value from the demand of withstand voltage at the time of rewriting operation of the memory. However, the thickness T1 of the insulating film can be made smaller than T2 irrespective of the demand of withstand voltage.

The flexibility of designing with respect to T1 is high in the sidewall memory cell for the following reason.

In the sidewall memory cell, the insulating film for separating the charge retaining film and the channel region or well region is not sandwiched by the gate electrode and the channel region or well region. Consequently, to the insulating film for separating the charge retaining film and the channel region or well region, a high electric field acting between the gate electrode and the channel region or well region does not directly act, but a relatively low electric field spreading from the gate electrode in the lateral direction acts. Consequently, irrespective of the demand of withstand voltage to the gate insulating film, T1 can be made smaller than T2.

By making T1 thinner, injection of charges into the memory functional unit becomes easier, the voltage of the writing operation and the erasing operation is decreased or the writing operation and erasing operation can be performed at high speed. Since the amount of charges induced in the channel region or well region when charges are accumulated in the silicon nitride film 242 increases, the memory effect can be increased.

The electric lines of force in the memory functional unit include a short one which does not pass through the silicon nitride film 242 as shown by an arrow 284 in FIG. 13. On the relatively short electric line of force, electric field intensity is relatively high, so that the electric field along the electric line of power plays a big role in the rewriting operation. By reducing T1, the silicon nitride film 242 is positioned downward in the figure, and the electric line of force indicated by the arrow 283 passes through the silicon nitride film. Consequently, the effective dielectric constant in the memory functional unit along the electric line 284 of force increases, and the potential difference at both ends of the electric line of force can be further decreased. Therefore, a large part of the voltage applied to the gate electrode 217 is used to increase the electric field in the offset region, and the writing operation and the erasing operation become faster.

In contrast, for example, in an EEPROM typified by a flash memory, the insulating film separating the floating gate and the channel region or well region is sandwiched by the gate electrode (control gate) and the channel region or well region, so that a high electric field from the gate electrode directly acts. Therefore, in an EEPROM, the thickness of the insulating film separating the floating gate and the channel region or well region is regulated, and optimization of the function of the sidewall memory cell is inhibited.

As obvious from the above, by setting T1<T2, without deteriorating the withstand voltage performance of the memory, the voltage of the writing and erasing operations is decreased, or the writing operation and erasing operation are performed at high speed and, further, the memory effect can be increased.

More preferably, the thickness T1 of the insulating film is 0.8 nm or more at which uniformity or quality by a manufacturing process can be maintained at a predetermined level and which is the limitation that the retention characteristic does not deteriorate extremely.

Concretely, in the case of a liquid crystal driver LSI requiring high withstand voltage in a design rule, to drive the liquid crystal panel TFT, voltage of 15 to 18 V at the maximum is required, so that the gate oxide film cannot be thinned normally. In the case of mounting a nonvolatile memory for image adjustment on the liquid crystal driver LSI, in the sidewall memory cell, the thickness of the insulating film separating the charge retaining film (silicon nitride film 242) and the channel region or well region can be designed optimally independently of the thickness of the gate insulating film. For example, the thickness can be individually set as T1=20 nm and T2=10 nm for a sidewall memory cell having a gate electrode length (word line width) of 250 nm, so that a sidewall memory cell having high writing efficiency can be realized (the reason why the short channel effect is not produced when T1 is larger than the thickness of a normal logic transistor is because the source and drain regions are offset from the gate electrode).

Eighth Embodiment

A sidewall memory cell in a semiconductor memory device of an eighth embodiment has a configuration substantially similar to that of the second embodiment except that, as shown in FIG. 18, the thickness (T1) of the insulating film separating the charge retaining film (silicon nitride film 242) and the channel region or well region is larger than the thickness (T2) of the gate insulating film.

The thickness T2 of the gate insulating film 214 has an upper limit value due to demand of preventing a short channel effect of the device. However, the thickness T1 of the insulating film can be made larger than T2 irrespective of the demand of preventing the short channel effect. Specifically, when reduction in scaling progresses (when reduction in thickness of the gate insulating film progresses), the thickness of the insulating film separating the charge retaining film (silicon nitride film 242) and the channel region or well region can be designed optimally independent of the gate insulating film thickness. Thus, an effect that the memory functional unit does not disturb scaling is obtained.

The reason why flexibility of designing T1 is high in the sidewall memory cell is that, as described already, the insulating film separating the charge retaining film and the channel region or well region is not sandwiched by the gate electrode and the channel region or well region. Consequently, irrespective of the demand of preventing the short channel effect for the gate insulating film, T1 can be made thicker than T2.

By making T1 thicker, dissipation of charges accumulated in the memory functional unit can be prevented and the retention characteristic of the memory can be improved.

Therefore, by setting T1>T2, the retention characteristic can be improved without deteriorating the short channel effect of the memory.

The thickness T1 of the insulating film is, preferably, 20 nm or less in consideration of decrease in rewriting speed.

Concretely, in a conventional nonvolatile memory typified by a flash memory, a selection gate electrode serves as a write erase gate electrode, and a gate insulating film (including a floating gate) corresponding to the write erase gate electrode also serves as a charge accumulating film. Since a demand for size reduction (thinning of a film is indispensable to suppress short channel effect) and a demand for assuring reliability (to suppress leak of retained charges, the thickness of the insulating film separating the floating gate and the channel region or well region cannot be reduced to about 7 nm or less) are contradictory, it is difficult to reduce the size. Actually, according to the ITRS (International Technology Roadmap for Semiconductors), there is no prospect of reduction in a physical gate length of about 0.2 micron or less. In the memory cell, since T1 and T2 can be individually designed as described above, size reduction is made possible.

For example, for a sidewall memory cell having a gate electrode length (word line width) of 45 nm, T2=4 nm and T1=7 nm are individually set, and a sidewall memory cell in which the short channel effect is not produced can be realized. The reason why the short channel effect is not produced even when T2 is set to be thicker than the thickness of a normal logic transistor is because the source/drain regions are offset from the gate electrode.

Since the source/drain regions are offset from the gate electrode in the sidewall memory cell, as compared with a normal logic transistor, reduction in size is further facilitated.

Since the electrode for assisting writing and erasing does not exist in the upper part of the memory functional unit, a high electric field acting between the electrode for assisting writing and erasing and the channel region or well region does not directly act on the insulating film separating the charge retaining film and the channel region or well region, but only a relatively low electric field which spreads in the horizontal direction from the gate electrode acts. Consequently, the sidewall memory cell having a gate length which is reduced to be equal to or less than the gate length of a logic transistor of the same process generation can be realized.

Ninth Embodiment

A ninth embodiment relates to a change in the electric characteristic at the time of rewriting a sidewall memory cell of a semiconductor memory device.

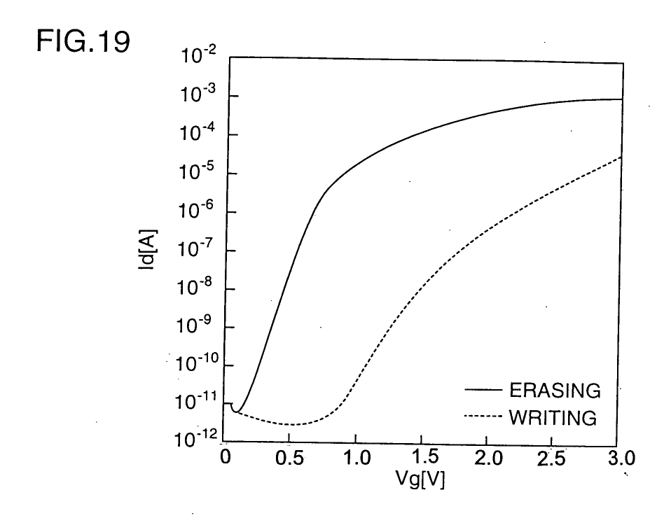

In an N-channel type sidewall memory cell, when an amount of charges in a memory functional unit changes, a drain current (Id)-gate voltage (Vg) characteristic (actual measurement value) as shown in FIG. 19 is exhibited.

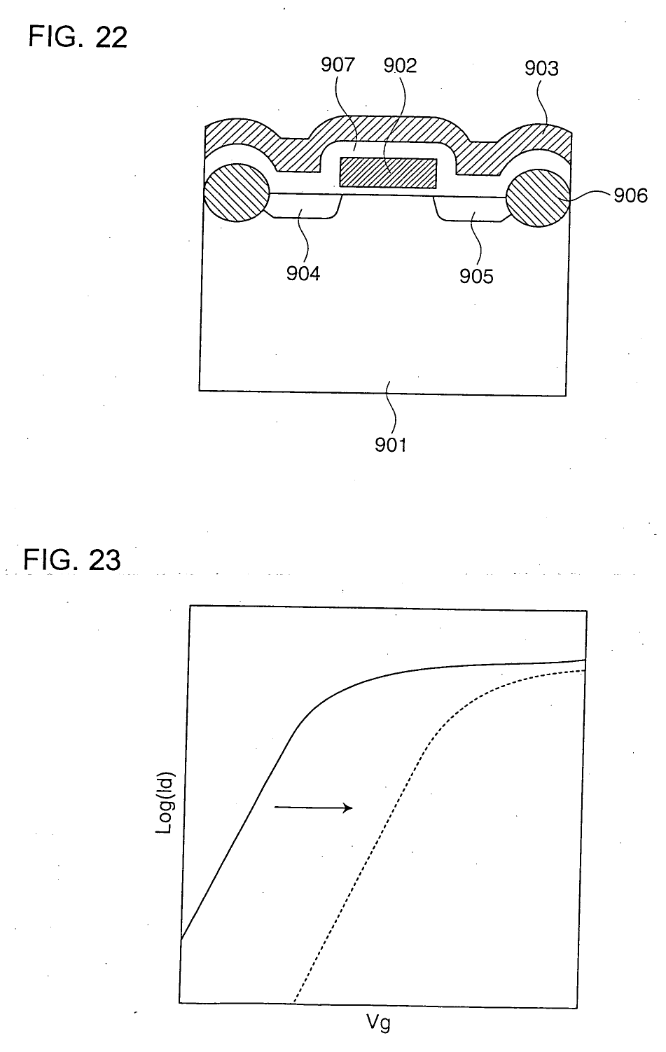

As obvious from FIG. 19, in the case of performing a writing operation in an erasing state (solid line), not only the threshold simply increases, but also the gradient of a graph remarkably decreases in a sub-threshold region. Consequently, also in a region where a gate voltage (Vg) is relatively high, the drain current ratio between the erasing state and the writing state is high. For example, also at Vg=2.5V, the current ratio of two digits or more is maintained. The characteristic is largely different from that in the case of a flash memory (FIG. 22).

Appearance of such a characteristic is a peculiar phenomenon which occurs since the gate electrode and the diffusion region are offset from each other, and the gate electric field does not easily reach the offset region. When the memory cell is in a writing state, even when a positive voltage is applied to the gate electrode, an inversion layer is extremely hard to be formed in the offset region under the memory functional unit. This is the cause that the gradient of the Id-Vg curve is gentle in the sub-threshold region in the writing state.

On the other hand, when the sidewall memory cell is in an erasing state, electrons of high density are induced in the offset region. Further, when 0 V is applied to the gate electrode (that is, when the gate electrode is in an off state), electrons are not induced in the channel below the gate electrode (consequently, an off-state current is small). This is the cause that the gradient of the Id-Vg curve is sharp in the sub-threshold region in the erasing state, and current increasing rate (conductance) is high in the region of the threshold or more.

As obviously understood from the above, in the sidewall memory cell in the semiconductor memory device of the present invention, the drain current ratio between the writing operation and the erasing operation can be particularly made high.

As described above in the first to ninth embodiments, the sidewall memory cell has an insulating film for insulating a film having a surface almost parallel with a surface of a gate insulating film and having the function of retaining charges from a channel region or a semiconductor layer. The insulating film is thinner than the gate insulating film and has a thickness of 0.8 nm or more, thereby facilitating injection of charges to a memory functional unit. Consequently, the writing operation can be performed at higher speed, and time for writing a reference cell can be shortened.

The memory functional unit of the sidewall memory cell includes the film having the surface almost parallel with the surface of the gate insulating film and having the function of retaining charges, thereby enabling variations in memory effects to be suppressed. In the embodiment using such a sidewall memory cell, a design margin for variations can be largely set and designing is facilitated.

In the sidewall memory cell, the charge retaining film in the memory functional unit is the insulating film. Thus, the sidewall memory cell is resistive to a charge leak, and has an excellent charge retention characteristic. Since the sidewall memory cell having the excellent charge retention characteristic is used and the current of a reference cell using the same sidewall memory cell is accurately set, reading can be performed for a longer period.

The sidewall memory cell includes the insulating film for separating a film having a surface almost parallel with the surface of the gate insulating film and having the function of retaining charges from a channel region or a semiconductor layer, and the insulating film is thicker than the gate insulating film and has a thickness of 20 nm or less, so that the charge retention characteristic is excellent. Since the sidewall memory cell having the excellent charge retention characteristic is used and current of a reference cell using the same sidewall memory cell is accurately set, reading can be performed for a longer period.

The memory functional unit of the sidewall memory cell includes the film having the surface almost parallel with the surface of the gate insulating film and having the function of retaining charges, thereby suppressing a characteristic change during retention. As described above, since the sidewall memory cell having the excellent charge retention characteristic is used and the current of the reference cell using the same sidewall memory cell is accurately set, reading operation can be performed for a longer period.

Tenth Embodiment

A tenth embodiment relates to a semiconductor memory device in which a memory cell array region 521 is formed more densely.

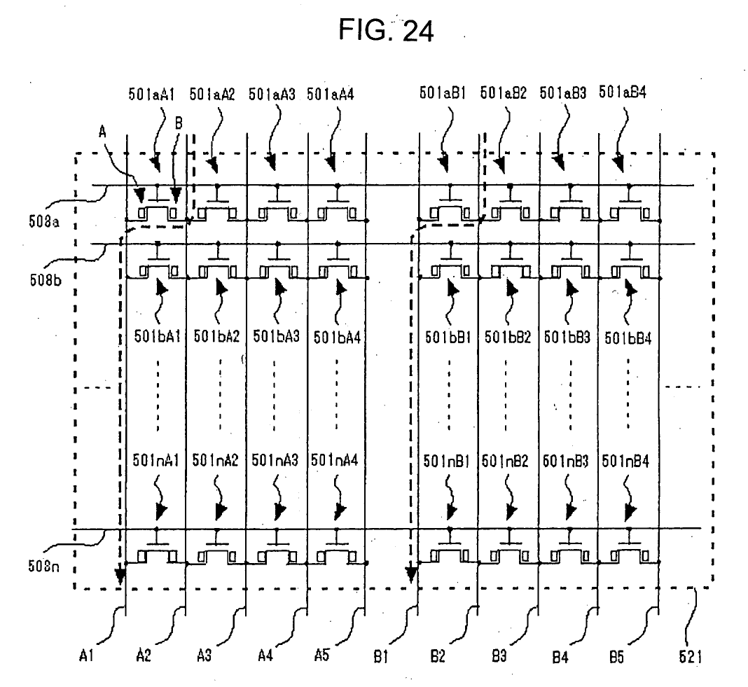

In FIG. 24, 501aA1 to 501aA4, 501aB1 to 501aB4, and 501nB1 to 501nB4 denote memory cells, 508a to 508n denote word lines, and BA1 to BA5 and BB1 to BB5 denote bit lines. A bit line is shared by memory cells belonging to neighboring columns. Concretely, bit lines A2 to A4 and B2 to B4 are shared. Although memory cells in four columns construct one block in the embodiment, the present invention is not limited to the number of columns.

In the semiconductor memory device, the reading operation is performed by passing current between two memory cells belonging to different blocks, specifically, the memory cells 501aA1 and 501bB1 to two input terminals of a sense amplifier and detecting the difference between the currents. In this case, for example, one of the input terminals of the sense amplifier is connected to a bit line A1, and the other input terminal is connected to a bit line B1. Further, a voltage proper for the reading operation (for example, +1.8V) is applied to the bit lines A2 and B2. Broken lines in FIG. 24 show paths of the current flown at this time. The currents flowing in the paths are supplied to the two input terminals of the sense amplifier, and the difference between the currents is detected. In FIG. 24, a circuit for connecting the memory cell, the voltage input terminal and the sense amplifier, and the like are not shown.

According to the semiconductor memory device of this embodiment, a bit line is shared by memory cells belonging to neighboring columns, so that the integrity can be largely improved. Therefore, the manufacture cost is largely reduced, and a cheap semiconductor memory device can be obtained.

Eleventh Embodiment

Here, description will be given of an example of programming with respect to a memory array configured by using a plurality of sidewall memory cells.

This programming is featured in that reading can be performed with respect to a memory cell at the same time when re-programming such as writing is performed with respect to another memory cell.

Further, as described later, in this embodiment, a memory cell unit includes at least two sidewall memory arrays and is featured by including two address registers, one multiplexer, one array selection circuit and a memory output unit. Moreover, one sidewall memory array (hereinafter abbreviated as “an SWA”) is constructed by a plurality of sidewall memory cells.

In the embodiment described below, the multiplexer is referred to as an input/output multiplexer; the array selection circuit, as an array selection circuit; and the memory output unit, as an input/output buffer.

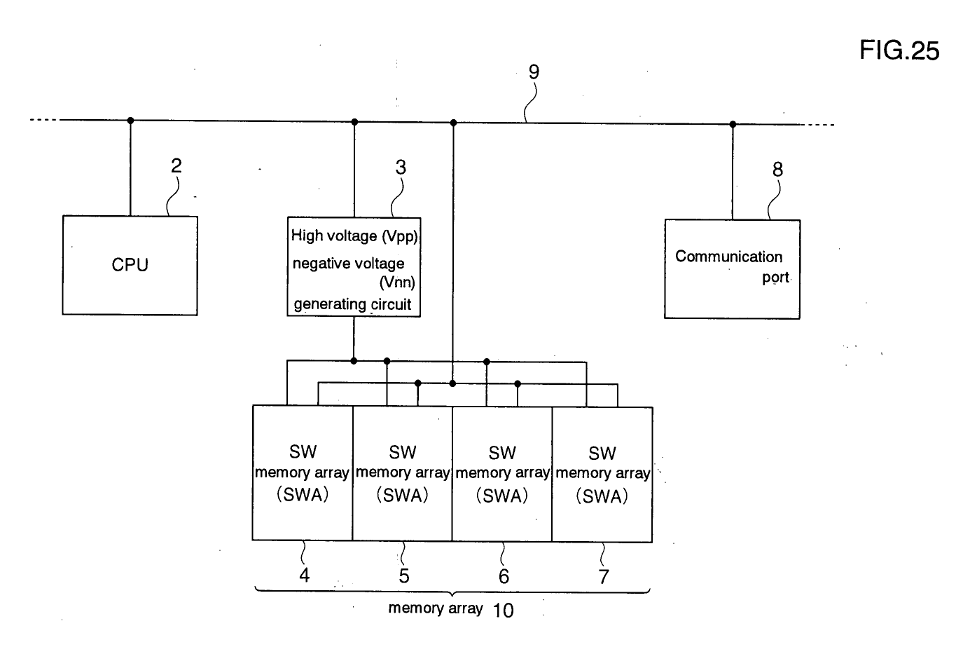

FIG. 25 is a configuration block diagram showing a microprocessor system MPS having the memory arrays constructed by the sidewall memory arrays according to the present invention.

This microprocessor system subjects a memory array 10 to ISW processes, to perform reading with respect to a memory cell when writing out of the ISW processes is performed with respect to another memory cell. In FIG. 25, the system MPS includes the memory array 10, a central processing unit (CPU) 2, a communication port 8, a Vpp generating circuit 3 and a bus 9.

The CPU 2 is a microprocessor in the system MPS. The CPU 2 mainly performs the ISW with respect to the memory array 10. The communication port 8 actuates as a communication medium with respect to another computer system (not shown), and the system MPS receives data for use in re-programming the memory array 10 via the communication port 8. The Vpp generating circuit 3 generates programming/erasing voltages (Vpp/Vnn) required for re-programming the memory cell 10. According to the present invention, Vpp designates a voltage of 6 V or more, for example, about 8 V. Via the bus 9 are mutually connected the CPU 2, the Vpp generating circuit 3, the memory array 10 and the communication port 8 in the system MPS.

In FIG. 25, the memory array 10 is constructed by four sidewall memory arrays SWAs (4, 5, 6 and 7). Here, the number of sidewall memory arrays SWAs is not limited to four. The memory arrays 4 to 7 are controlled by the CPU 2 independently of each other. Specifically, the memory arrays 4 to 7 can be read, programmed or erased independently of each other. The memory array 10 is mounted on a single substrate. Although the memory arrays SWAs 4 to 7 are provided with their own address registers, decoders and the like, respectively, they commonly use other peripheral circuits required for the operation in the memory array 10. With this arrangement, when the programming is performed in one of the memory arrays SWAs, access (for example, memory cell reading) is made to the other memory array SWA.

For example, the CPU 2 performs reading of the memory array SWA 7 while performing erasing/re-programming of the memory array SWA 4. Specifically, in this embodiment, the CPU 2 can perform a task required to have access to information stored in the memory cell 10 at the same time during the re-programming of the memory cell 10.

Otherwise, in another embodiment, booting information may be stored in the memory cell 10. Since the memory cell 10 has a dual array structure, the booting information can be held in or read from the memory cell 10 even during the re-programming.

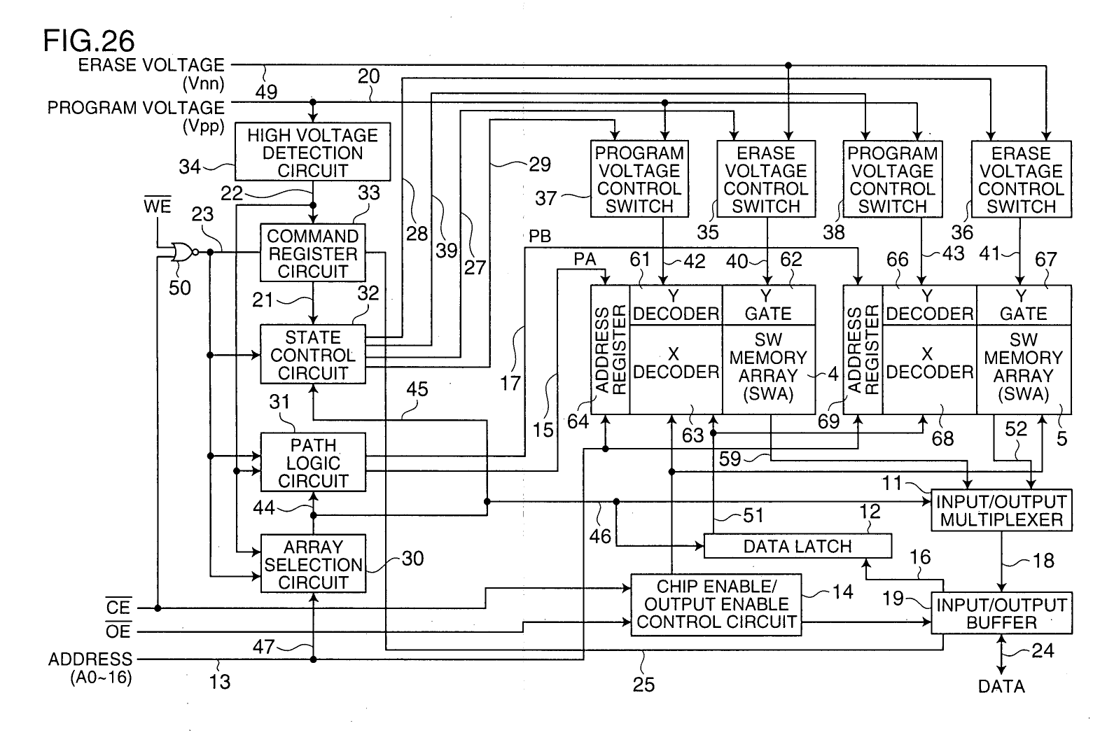

FIG. 26 is a block diagram showing the memory cell 10. In FIG. 26, the memory cell 10 is provided with the two sidewall memory arrays SWAs 4 and 5, each of which is constructed by a plurality of sidewall memory cells (not shown) for storing therein data and addresses. For example, each of the memory arrays SWAs 4 and 5 has a data storing capacity of 512 Kbit (KB), although the data storing capacity is not limited to this value.

Alternatively, the memory array 10 may be constructed by a complementary metal oxide semiconductor (CMOS) circuit mounted on a single substrate. Each of the memory arrays SWAs 4 and 5 may have a so-called matrix structure. In this case, the memory cell of each of the memory arrays SWAs 4 and 5 is located at an intersection of a word line (not shown) and a bit line (not shown).

For example, the memory array 10 may have the array arrangement shown in FIG. 24.

The word line of each of the memory arrays SWAs 4 and 5 is connected to a control gate of the memory cell arranged inside of one row. The bit line of each of the memory arrays SWAs 4 and 5 is connected to a drain region of the memory cell arranged inside of one column.

Otherwise, each of the memory arrays SWAs 4 and 5 may be constructed by a plurality of bit line blocks, in which the bit lines are divided into a plurality of groups. Alternatively, each of the memory arrays SWAs 4 and 5 may be constructed by a plurality of word line blocks, in which the word lines are divided into a plurality of groups.

In the case where each of the memory arrays SWAs 4 and 5 has a bit line block structure, each of the blocks includes the plurality of bit lines. The word line passes all of the blocks in one memory array; therefore, the memory cells in all of the blocks in that memory array commonly use the word line.

In the case where each of the memory arrays SWAs 4 and 5 has a word line block structure, each of the blocks includes the plurality of word lines. The bit line passes all of the blocks in one memory array; therefore, the memory cells in all of the blocks in that memory array commonly use the bit line.

Otherwise, each of the memory arrays SWAs 4 and 5 may be constructed by one 8 K byte booting block and two 4 K byte parameter blocks. In one example, the booting block stores therein booting codes for system initialization, re-programming algorithm and communication software; and the parameter block stores therein frequently updated system parameters and constitutional information. Since the booting block is not frequently updated, there is provided a re-programming/writing lock-out function as the function of securing the consistency of the data.

In FIG. 26, in addition to the arrays SWAs 4 and 5, the memory array 10 includes an input/output multiplexer 11, a data latch 12 and an input/output buffer 19. The input/output multiplexer 11 is connected to the memory arrays SWAs 4 and 5 via buses 59 and 52, respectively. The input/output multiplexer 11 supplies an output representing data stored in the memory array SWA 4 or 5 to the input/output buffer 19 via a bus 18. The output data is sent to an external circuit (not shown) via a bus 24, which is a bidirectional bus. Data to be programmed in the memory array 10 is first latched to the input/output buffer 19 via the bus 24 and, thereafter, is sent to the data latch 12 via a bus 16. The data latch 12 is connected to the memory arrays SWAs 4 and 5 via a bus 51.

Vnn and Vpp denote erasing/programming power source voltages of the memory array 10, respectively. A system power source voltage Vcc or a ground voltage Vss also is input, although not shown. For example, the voltage Vpp is set to 6 V or more; and the voltage Vcc is set to about 3.0 V. When there is no voltage Vpp of a high value in a Vpp input pin, the memory array 10 functions as a read only memory. Data stored at an address supplied via an address bus 13 is read from the memory array SWA 4 or 5. The data is supplied to the input/output buffer 19 via the input/output multiplexer 11 and the bus 52 or the bus 18. Subsequently, the data is sent to the external circuit via the bus 24. The memory array 10 has two control functional inputs: a chip enable CE (bar) input and an output enable OE (bar) input. The chip enable input CE (bar) is an electric power control input, and is used for system selection. The output enable input OE (bar) is an output control input of the memory array 10, and has the function of allowing the data sent from an output pin to pass irrespective of the system selection. Both of the control function CE (bar) and OE (bar) must be logically active LOW in such a manner as to obtain the data at the output of the memory array 10.

An X decoder 63 is a row decoder in the memory array SWA 4; a Y decoder 61 is a column decoder in the memory array SWA 4; and an address register 64 is an address register in the memory array SWA 4. An X decoder 68 is a row decoder in the memory array SWA 5; a Y decoder 66 is a column decoder in the memory array SWA 5; and an address register 69 is an address register in the memory array SWA 5.

The address register 64 receives an address of the memory array SWA 4 via the address bus 13. The address register 74 receives an address of the memory array SWA 5 via the address bus 13. Each of the address registers 64 and 69 receives an address of the corresponding memory array via the address bus 13 during a reading operation, a programming operation or an erasing operation. The X decoder 68 connects all of the word lines to the memory array SWA 4. The X decoder 68 receives an X address from the address register SWA 4. The X decoder 68 selects one of the word lines in accordance with each of the addresses supplied from the address register SWA 4 during the reading operation or the programming operation.

The Y decoder 61 is connected to all of the bit lines in the memory array SWA 4 via a Y gate circuit 62. The Y decoder 61 receives a Y address from the address register 64. The Y decoder 61 selects the bit lines corresponding to one byte (that is, eight bit lines) relative to each of the Y addresses supplied from the address register 64 during the reading operation or the programming operation. The Y gate circuit 62 also is connected to the input/output multiplexer 11 via the bus 59, and is connected to the data latch 12 via the bus 51.

The X decoder 68 connects all of the word lines to the memory array SWA 5. The X decoder 68 receives an X address from the address register 69. The X decoder 68 selects one of the word lines in accordance with each of the X addresses supplied from the address register 69 during the reading operation or the programming operation. The Y decoder 66 is connected to all of the bit lines in the memory array SWA 5 via a Y gate circuit 67. The Y decoder 66 receives a Y address from the address register 69. The Y decoder 66 selects the bit lines corresponding to one byte (that is, eight bit lines) relative to each of the addresses supplied from the address register 69 during the reading operation or the programming operation. The Y gate circuit 67 also is connected to the input/output multiplexer 11 via the bus 59, and is connected to the data latch 12 via the bus 51.

The address is supplied to the X decoder 68 and the Y decoder 66 from the address register 69 during the programming of the memory cell in the memory array SWA 5. The X decoder 68 selects one of the word lines relative to the supplied X address and, then, sends a word line programming voltage (for example, 5 V) to the selected word line. The Y decoder 66 selects the bit lines corresponding to one byte relative to the supplied Y address, and then, sends a bit line programming voltage (for example, 5 V) to the selected bit line.

Erasure of the memory array SWA 4 or 5 can achieve erasure with respect to all of the arrays. In order to erase all of the arrays, a voltage of, for example, 5 V is applied to a source and a drain of each of the memory cells of one of the memory arrays SWAs in the memory array 10. Next, a voltage of −5 V is applied to each of the word lines in the memory cell.

Also in the case where the memory array SWA 4 or 5 is constructed by a plurality of blocks, all of the arrays or blocks can be erased.

As one example, the memory array SWA 4 may be constructed by blocks including a plurality of word lines in one embodiment according to the present invention.

Otherwise, the memory array SWA 4 may be constructed by blocks including a plurality of bit lines.

In FIG. 26, as constituent elements of the memory array 10 are provided a command register circuit 33 and a state control circuit 32. The state control circuit 32 functions as an internal state machine for the memory array 10. The command register circuit 33 per se does not have an addressable memory position, and is a latch for storing therein a command together with the address and data information required for executing a command. Three operations, that is, data reading, data programming and reading, and data erasing and reading may be controlled in the memory array 10.

The operation is selected by writing a specified command in the command register circuit 33 via the bus 24 and a bus 25. The command is written in the command register circuit 33 via the buses 24 and 25 by the CPU 2 or another external microprocessor shown in FIG. 25. Standard commands include, for example, an erasing command, an erasure inspecting command, a programming command, a program inspecting command and a reading command. For example, in the case where the CPU 2 issues the erasing command, the contents of the command register circuit 33 may be defaulted to an erasing/reading command. Otherwise, in the case where the CPU 2 issues the programming command, the contents of the command register circuit 33 may be defaulted to a programming/reading command. In the case where a Vpp voltage of 12 V is applied to a voltage line 20, the state of the command register circuit 33 is switched. The voltage Vpp is received by a high voltage detection circuit 34 through the line 20 and, then, a signal Vpph representing the high voltage Vpp is sent to the command register circuit 33 through a line 22. The command register circuit 33 sends a signal for starting the erasing and programming of the memory arrays SWAs 4 and 5 to the state control circuit 32 accordingly.

When the high voltage Vpp is extinguished, the signal Vpph becomes LOW and, then, the contents of the command register circuit 33 is defaulted to the reading command. In this case, the memory array 10 functions as a read only memory. Furthermore, the voltage Vpp may be supplied to the command register circuit 33 at all times. In this case, all of the operations by the memory array 10 are performed in cooperation with the command register circuit 33.

In FIG. 26, a command input into the command register circuit 33 is supplied from the CPU 2. This command is supplied via the bus 24, the input/output buffer 19 and the bus 25 in sequence. The command is written in the command register circuit 33 by setting a writing enable WE (bar) signal to a logic low level when the chip enable signal CE (bar) is LOW. When the CE (bar) signal is active LOW, a NOR gate 50 allows the WE (bar) signal to pass. An output of the NOR gate 50 is connected to the command register circuit 33, the state control circuit 32 and an array selection circuit 30. The writing enable WE (bar) signal is active LOW. An address is latched in the address register 64 or the address register 69 at the time of falling of a writing enable pulse. The command is latched in the command register circuit 33 and the data latch 12 at the time of rising of the writing enable pulse WE (bar). The erasing/programming operation is started at the time of rising of the WE (bar). A standard microprocessor writing timing may be used, although the writing enable pulse WE (bar) is supplied by the CPU 2 here.

The state control circuit 32 receives an input from the command register circuit 33 via a bus 21. The state control circuit 32 is adapted to control the operation of the memory array 10. Specifically, the state control circuit 32 controls erasure voltage switches 35 and 36 and program voltage switches 37 and 38, thereby controlling the erasing/programming operation of the memory arrays SWAs 4 and 5. Furthermore, the state control circuit 32 controls the latch of the addresses to the address registers 64 and 69. Moreover, the state control circuit 32 controls the latch of the data to the data latch 12. An STB signal as one output from the state control circuit 32 is sent to the address registers 64 and 69 and the data latch 12. An address is latched in the address register 64 or the address register 69 in accordance with the STB signal at the time of falling of the writing enable signal WE (bar). The address is latched in the data latch 12 in accordance with the STB signal at the time of rising of the writing enable signal WE (bar). An erase enable signal SELVPS1 as another output from the state control circuit 32 is sent to the erase voltage switch 35 via a line 27. The erase voltage switch 35 is an erase voltage switch for the memory array SWA 4.

An erase enable signal SELVPS2 as still another output from the state control circuit 32 is sent to the erase voltage switch 36 via a line 28. The erase voltage switch 36 is an erase voltage switch for the memory array SWA 5. The high voltage Vpp is applied to the erase voltage switch 36 via the line 20. The erase voltage switch 36 receives the erase enable signal SELVPS2 of logic HIGH via the line 28. Then, the erasure voltage Vpp is sent to a source of the memory cell in the memory array SWA 5 via a line 41 through the line 20, thereby starting electric erasure in the memory array SWA 5. In the case where the memory cell in the memory array SWA 5 has the block structure, the voltage Vpp on the line 41 is first supplied to the block decoder in the memory array SWA 5, thereby starting the erasure of a block in the memory array SWA 5, designated by a block address supplied to the memory array SWA 5. When the erase enable signal SELVPS2 on the line 28 logically becomes LOW, the erase voltage switch 36 stops the supply of the high voltage Vpp on the line 41, so that the voltage on the line 41 becomes 0 V, thereby stopping the erasing process of the memory array SWA 5.

A program enable bar signal PROB1 of the memory array SWA 4 as yet another output from the state control circuit 32 is sent to the program voltage switch 37 via a line 29. The high program voltage Vpp is applied to the program voltage switch 37 via the line 20. When the voltage PROB1 on the line 29 is logic LOW, the program voltage switch 37 supplies the voltage Vpp to the X decoder 63 and the Y decoder 61 via a line 42, thereby starting the programming operation in the memory array SWA 4. The voltage Vpp is decreased down to a program voltage Vp in the Y decoder 61.

An X address in the memory array SWA 4 is supplied to the X decoder 63 from the address register 64. In response to the X address, the X decoder 63 selects one word line, to apply the voltage Vpp to the selected word line. A Y address in the memory array SWA 4 is supplied to the Y decoder 61 from the address register 64. In response to the Y address, the Y decoder 61 selects the bit lines corresponding to 1 byte, to apply the voltage Vp to the selected bit lines. Data to be programmed in the memory array SWA 4 is latched in the data latch 12 via the input/output buffer 19 and the buses 24 and 16. The Y gate circuit 62 receives the data from the data latch 12 via the bus 51, to confirm the bit lines, to which the voltage Vp is to be applied. In other words, the application of the voltage Vp to the selected bit lines depends on the data latched in the data latch 12.

When the program enable bar signal PROB1 on the line 29 is logic HIGH, the voltage on the line 42 becomes 0 V, so that the program operation in the memory array SWA 4 is ended. A program enable bar signal PROB2 of the memory array SWA 5 as yet another output from the state control circuit 32 is sent to the program voltage switch 38 via a line 39. The voltage Vpp is applied to the program voltage switch 38 via the line 20. When the voltage PROB2 on a line 39 is logic LOW, the program voltage switch 38 supplies the voltage Vpp to the X decoder 68 and the Y decoder 66 via a line 43, thereby starting the programming operation in the memory array SWA 5. The voltage Vpp is decreased down to the program voltage Vp in the Y decoder 66. The X decoder 68 receives the X address from the address register 69, selects one word line, and applies the voltage Vpp to the selected word line. The Y decoder 66 receives the Y address from the address register 69 in the memory array SWA 5, selects the bit lines corresponding to 1 byte, and applies the voltage Vp to the selected bit lines.

Data to be programmed in the memory array SWA 5 is latched in the data latch 12 via the input/output buffer 19 and the buses 24 and 16. The Y gate circuit 67 receives the data from the data latch 12 via the bus 51, to confirm the bit lines, to which the voltage Vp is to be applied. At this time, the application of the voltage Vp to the selected bit lines depends on the data latched in the data latch 12. When the program enable bar signal PROB2 on the line 39 becomes logic HIGH, the voltage on the line 43 becomes 0 V, so that the programming operation in the memory array SWA 5 is ended.

Otherwise, the memory array 10 may be equipped with an automatic internal writing function. The automatic internal writing function can alleviate a burden on the CPU 2 for controlling the memory array 10. In order to equip the automatic internal writing function, a writing state control circuit is used in place of the state control circuit 32. The writing state control circuit stores therein erasing algorithm and programming algorithm. The writing state control circuit controls a programming inspection mode and an erasing inspection mode. Upon reception of the erasing command or the programming command by the memory array 10, the writing state control circuit controls the sequencing of various kinds of circuits in the memory array 10, that is, controls a programming operation, a program inspecting operation, an erasing operation and an erasure inspecting operation. Thus, the CPU 2 can concentrate attention on other tasks.

The CPU 2 can grasp the state of the writing state control circuit at all times by making access to a state register in a writing state controller. This state register stores therein the state of the writing state control circuit. The writing state control circuit is provided with, for example, a period counter, an event counter, a next state controller, an oscillator phase generator, a synchronizing circuit and a data latching/comparing circuit.

The period counter is adapted to generate a program/erasure pulse width and four independent periods of an inspection delay. The event counter is designed to set a limit value of the number of program/erasure pulses to be applied to the memory array SWA 4 or 5. The oscillator phase generator is adapted to generate a clock signal for use in the synchronizing circuit. The synchronizing circuit is designed to synchronize the command register circuit 33 with the writing state control circuit. The data latching/comparing circuit is adapted to compare the output from the input/output multiplexer 11 with the data latched in the data latching/comparing circuit, thereby performing re-programming. The next state controller is designed to control and integrate various kinds of activities in the writing state control circuit, so as to confirm a next state of the writing state control circuit. A command port disposed in the writing state control circuit functions as an interface between the writing state control circuit and the CPU 2.

In FIG. 26, the memory array 10 further includes the array selection circuit 30 and a path logic circuit 31. The array selection circuit 30 is adapted to select a memory array to be re-programmed or a memory array to be read. The array selection circuit 30 sends a control signal AS to the path logic circuit 31 via a line 44, to the state control circuit 32 via a line 45, and to the input/output multiplexer 11 via a line 46. The path logic circuit 31 controls to latch the addresses to the address register 64 and the address register 69. A PASSA signal as one output signal from the path logic circuit 31 is sent to the address register 64 via a line 15. The PASSA signal controls the latching of the address to the address register 64. A PASSB signal as another output signal from the path logic circuit 31 is sent to the address register 69 via a line 17. The PASSB signal controls the latching of the address to the address register 69.

According to the present invention, address information including 17 bits (that is, bits A0 to A16) is used as the address to be sent via the address bus 13. The 16 bits A0 to A15 constitute an array address to be latched to the address register 64 or the address register 69. The residual bit A16 is an array select bit. The array select bit A16 is array selecting information for determining to which of the memory arrays SWAs 4 and 5 the memory address is given. Incidentally, one of the address bits A0 to A15 may be used as the array selection bit.

The voltage Vpp cannot be applied to the memory array 10 during the reading operation of the memory array SWA 4 or 5. Consequently, the output signal Vpph of the high voltage detection circuit 34 is logic LOW. An address is sent to the address bus 13. The address bit A16 is sent to the array selection circuit 30 via a line 47. For example, the address bit A16 of logic LOW selects the memory array SWA 4; in contrast, the address bit A16 of logic HIGH selects the memory array SWA 5. The function of the low Vpph signal allows the A16 signal to pass the array selection circuit 30, thereby generating the AS signal. The AS signal is sent to the state control circuit 32 via the line 45 and to the input/output multiplexer 11 via the line 46. Furthermore, the AS signal is input into the path logic circuit 31 from the array selection circuit 30 via the line 44. However, since the low Vpph signal is sent to the path logic circuit 31, the path logic circuit 31 cannot operate with respect to the AS signal. Both of the output signals PASSA and PASSB from the path logic circuit 31 are defaulted to logic HIGH. The high signals PASSA and PASSB enable the address registers 64 and 69. The address from the address bus 13 is given to both of the address registers 64 and 69, so that the reading operation in both of the memory arrays SWAs 4 and 5 is performed.

The input/output multiplexer 11 confirms as to whether the output of either of the arrays SWAs 4 or 5 is connected to the input/output buffer 19. The AS signal to be supplied to the input/output multiplexer 11 controls the input/output multiplexer 11. When the bit A16 is logic LOW, the input/output multiplexer 11 sends the data via the bus 59 to the bus 18. The data via the bus 52 cannot be sent to the bus 18. In other words, only the data read from the memory array SWA 4 is sent to the input/output buffer 19. In contrast, when the bit A16 is logic HIGH, the input/output multiplexer 11 sends the data via the bus 52 to the bus 18. In other words, only the data read from the memory array SWA 5 is sent to the input/output buffer 19. The voltage Vpp is applied to the memory array 10 during the erasing and reading operations. The high voltage detection circuit 34 generates the logic HIGH Vpph signal. The CPU 2 sends an erasing command to the command register circuit 33. An erasing address instructing a memory array to be subjected to the erasing process is sent to the address bus 13. The address bit A16 of the address is sent to the array selection circuit 30 via the line 47. In the embodiment in which each of the memory arrays SWAs 4 and 5 has the block structure, the erasing address also includes information instructing a block to be erased.

When the Vpph signal is set to a logic HIGH level, the array selection circuit 30 functions as a latch. The array selection circuit 30 latches the address selection bit A16 under the control of the WE (bar) signal. When the WE (bar) signal is set to a logic LOW level, the array selection circuit 30 latches the bit A16 at a falling edge of the WE (bar) signal. The bit A16 latched by the array selection circuit 30 is turned into the AS signal and, then, is sent to the path logic circuit 31 via the line 44. If the AS signal to be supplied to the path logic circuit 31 is logic LOW (that is, the bit A16 is logic LOW), the path logic circuit 31 generates the logic LOW signal PASSA and the logic HIGH signal PASSB. If the AS signal to be supplied to the path logic circuit 31 is logic HIGH (that is, the bit A16 is logic HIGH), the path logic circuit 31 generates the logic HIGH signal PASSA and the logic LOW signal PASSB. In other words, the signal PASSA and the signal PASSB establish the complementary relationship.

When the AS signal is LOW, the logic LOW signal PASSA is sent to the address register 64 while the logic HIGH signal PASSB is sent to the address register 69. The address register 64 latches an erasing address to be sent from the bus 13 under the control of the STB signal to be supplied from the state control circuit 32. The STB signal is logic active LOW signal. The address register 64 latches the erasing address at the time of falling of the STB signal. The logic HIGH signal PASSB enables the address register 69; accordingly, the address register 69 reads a subsequent address to be supplied via the line 13.

Furthermore, the AS signal is sent to the state control circuit 32 via the line 45. When the AS signal is logic LOW, the state control circuit 32 sends the logic HIGH erasure enable signal SELVPS1 to the erase voltage control switch 35 while maintaining the signal SELVPS2 to logic LOW. When the AS signal is logic HIGH, the state control circuit 32 sends the logic HIGH erasure enable signal SELVPS2 to the erase voltage control switch 36 while maintaining the signal SELVPS1 to logic LOW. When the signal SELVPS1 is logic HIGH while the signal SELVPS2 is logic LOW, the voltage Vpp to be supplied in one of the erasing processes is supplied to the memory array SWA 4 via the line 40. Erasure initialization is carried out in the memory arrays SWA 4, but is not carried out in the memory arrays SWA 5. When the signal PASSB is set to a logic HIGH level, the address register 69 cannot function as a latch. All of the subsequent addresses to be sent to the address bus 13 are sent to the memory arrays SWA 5 through the address register 69 in one of the reading operations. The data read from the memory arrays SWA 5 is sent to the input/output multiplexer 11 via the bus 52. In this case, the AS signal also controls the input/output multiplexer 11, so that the data read from the memory array SWA 5 is sent to the input/output buffer 19.

However, when the Vpph signal is set to a logic HIGH level and the WE (bar) signal is active LOW, the reading operation in the memory array SWA 4 is inhibited. The erase address is latched to the address register 64. However, when the AS signal is logic HIGH, the logic HIGH signal PASSA is sent to the address register 64 while the logic LOW signal PASSB is sent to the address register 64. The AS signal of logic HIGH signifies that the signal SELVPS2 is logic HIGH while the signal SELVPS1 is logic LOW. The Vpp signal is sent to the memory array SWA 5 but not to the memory array SWA 4. The memory array SWA 5 latches the erase address. Then, the erasure is started in the memory array SWA 5. Thereafter, the address register 64 is enabled, so that the memory array SWA 4 can be read. The input/output multiplexer 11 sends the data read from the memory array SWA 4 to the input/output buffer 19 via the buses 59 and 18.

The high voltage Vpp is applied to the Vpp pin in the memory array 10 during the programming/reading operation. The high voltage detection circuit 34 detects the voltage Vpp and, then, sends the signal Vpph of logic HIGH to the array selection circuit 30 and the path logic circuit 31. The CPU 2 sends the WE (bar) signal to the command register circuit 33. A program address is sent to the address bus 13. The address bit A16 is sent to the array selection circuit 30 via the line 47. That is to say, the address bit A16 instructs a memory array to be programmed. When the Vpph signal is set to a logic HIGH level, the array selection circuit 30 functions as the latch. The array selection circuit 30 latches the address select bit A16 under the control of the WE (bar) signal. The array selection circuit 30 latches the bit A16 at the time of the falling of the WE (bar) signal. The address select bit A16 latched by the array selection circuit 30 is turned into the AS signal and, then, is sent to the path logic circuit 31 via the line 44.

If the AS signal to be supplied to the path logic circuit 31 is logic LOW (that is, the bit A16 is logic LOW), the path logic circuit 31 generates the logic LOW signal PASSA and the logic HIGH signal PASSB. The AS signal to be supplied to the path logic circuit 31 is logic HIGH (that is, the bit A16 is logic HIGH), the path logic circuit 31 generates the logic HIGH signal PASSA and the logic LOW signal PASSB. When the AS signal is HIGH, the logic HIGH signal PASSA is sent to the address register 64 while the logic LOW signal PASSB is sent to the address register 69. The address register 64 latches the program address to be sent from the bus 13 under the control of the STB signal to be supplied from the state control circuit 32. The address register 69 latches the address at the time of falling of the STB signal.

The data to be programmed is latched to the data latch 12 under the control of the STB signal. The data is latched to the data latch 12 at the time of rising of the STB signal. Furthermore, the AS signal is sent to the state control circuit 32 via the line 45. When the AS signal is logic HIGH, the state control circuit 32 sends a program enable bar signal PROB2 of logic LOW to the program voltage control switch 38, and maintains the program enable bar signal PROB2 to a logic HIGH level. In contrast, when the AS signal is logic LOW, the state control circuit 32 sends a program enable bar signal PROB1 of logic LOW to the program voltage control switch 37, and maintains the program enable bar signal PROB2 to a logic HIGH level.

When the AS signal is logic HIGH, the signal PROB2 is logic LOW and the signal PROB1 is logic HIGH, the program high voltage Vpp is sent to the X decoder 68 and the Y decoder 66 via the line 43. The program high voltage Vpp is decreased to the Vp voltage level in the Y decoder 66; accordingly, the programming operation in the memory array SWA 5 is started. In the case where the PASSA signal supplied from the path logic circuit 31 is logic HIGH, the address register 64 cannot function as the latch but it is enabled in response to the high voltage PASSA signal. All of the subsequent addresses to be sent to the address bus 13 are sent to the memory array SWA 5 through the address register 64 in one of the reading operations. The data read from the memory array SWA 4 is sent to the input/output multiplexer 11 via the bus 59 under the control of the AS signal.

However, when the AS signal is logic LOW, the logic LOW signal PASSA is sent to the address register 64 while the logic HIGH signal PASSB is sent to the address register 69. The AS signal of logic LOW signifies that the signal PROB1 is logic LOW while the signal PROB 2 is logic HIGH. Subsequently, the program high voltage Vpp is sent to the Y decoder 61 and the X decoder 63 in the memory array SWA 4. The voltage Vpp is decreased to the Vp voltage in the Y decoder 61. The address register 64 latches the program address. The data latch 12 latches the data to be programmed. The programming of the memory array SWA 4 is started. The address register 69 is enabled, so that the memory array SWA 5 can be read. The input/output multiplexer 11 sends the data read from the memory arrays SWA 5 to the input/output buffer 19 via the buses 52 and 18.

Otherwise, according to the present invention, a booting block (not shown) for storing therein booting information may be provided in each of the memory arrays SWAs 4 and 5. For example, the booting information may include the system initialization information and the re-programming information. The booting block requires updating to a minimum level. When the memory array SWA 4 is re-programmed, the CPU 2 can make access to the booting information stored in the booting block in the memory array SWA 5 by the reading operation. In contrast, when the memory array SWA 5 is re-programmed, the CPU 2 can utilize the reading operation in order to make access to the block in the memory array SWA 4 for the booting information.

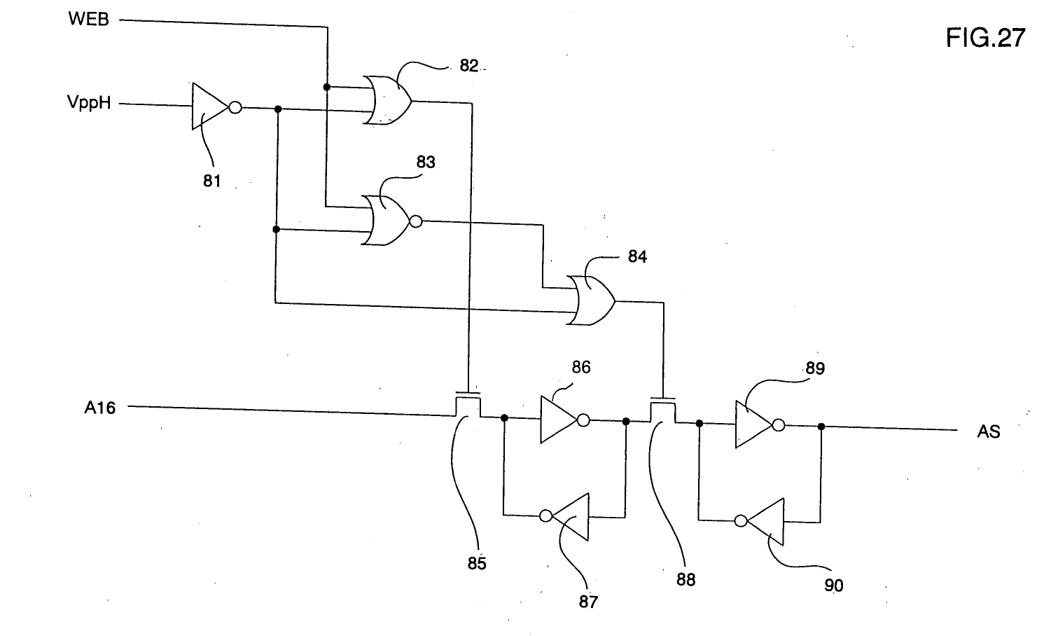

FIG. 27 is a block diagram showing the array selection circuit 30. The array selection circuit 30 includes a first latch including inverters 86 and 87 and a second latch including inverters 89 and 90. Here, each of the transistors 85 and 88 is an N-channel transistor. An output of the first latch is connected to a drain of the second gate transistor 88. Incidentally, each of the transistors 85 and 88 may be a P-channel transistor.

The WE (bar) signal as an input is sent to an OR gate 82. The Vpph signal as an input is sent to an inverter 81. An output from the inverter 90 as another input is sent to the OR gate 82. An output from the OR gate 82 is connected to a gate of the transistor 85. A drain of the transistor 85 is connected to the address bit A16 as the array selection bit. The A16 signal is supplied to the array selection circuit 30 via the line 47 (see FIG. 26). When the transistor 85 is turned ON in response to the WE (bar) signal or the Vpph signal, the A16 signal passes through the transistor 85, to be thus sent into the first latch including the inverters 86 and 87. If the transistor 88 is turned OFF, the A16 signal is latched to the first latch and, then, is held in the first latch. In contrast, if the transistor 88 is turned ON, the A16 signal passes through the transistor 88, to be thus sent into the second latch including the inverters 89 and 90. The A16 signal serves as the output signal AS for the array selection circuit 30.

Furthermore, the WE (bar) signal is sent to an input of a NOR gate 83. Moreover, an output of the inverter 81 is connected to another input of the NOR gate 83. An output of the NOR gate 83 is connected to an input of an OR gate 84. Additionally, the output of the inverter 81 is connected to another input of the OR gate 84. An output of the OR gate 84 is connected to a gate of the transistor 88. If the Vpph signal is logic LOW (this signifies that the memory array 10 functions as a read only memory), the outputs of the OR gates 82 and 84 are logic HIGH, so that both of the transistors 85 and 88 are turned ON. Consequently, the array selection circuit 30 cannot respond to the WE (bar) signal; therefore, the A16 signal passes the circuit 30, to thus serve as the AS output.

If the Vpph signal is logic HIGH (this signifies that the memory array 10 can be erased or programmed), both of the transistors 85 and 88 are controlled in response to the WE (bar) signal. If the WE (bar) signal is logic HIGH, the transistor 85 is ON while the transistor 88 is OFF. The A16 signal is latched to the first latch (that is, the inverters 86 and 87) and, then, is held in the first latch. If the WE (bar) signal is logic LOW, the transistor 88 is ON while the transistor 85 is OFF. As a consequence, the A16 signal is sent from the first latch to the second latch including the inverters 89 and 90. The output from the second latch is the AS signal.

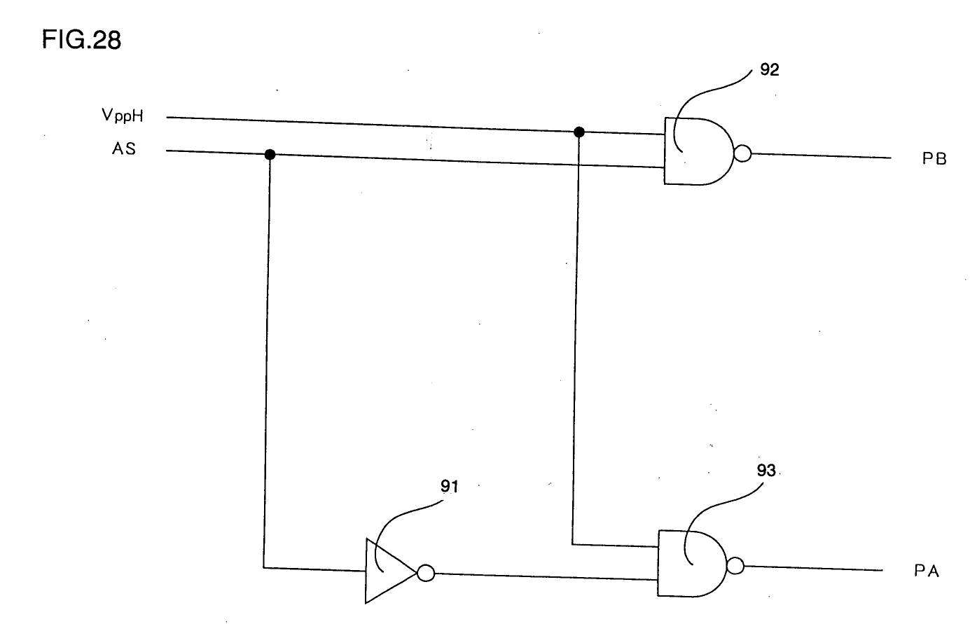

FIG. 28 is a block diagram showing the path logic circuit 31. The path logic circuit 31 includes an inverter 91 and NAND gates 92 and 93. If the Vpph signal is logic LOW (this signifies that the memory array 10 functions as a read only memory), both of the PASSA signal and the PASSB signal are logic HIGH irrespective of the AS signal. In contrast, if the Vpph signal is logic HIGH, the PASSA signal and the PASSB signal are controlled in response to the AS signal. If the AS signal is logic LOW, the PASSA signal becomes LOW while the PASSB signal becomes HIGH. In contrast, if the AS signal is logic HIGH, the PASSA signal becomes HIGH while the PASSB signal becomes LOW.

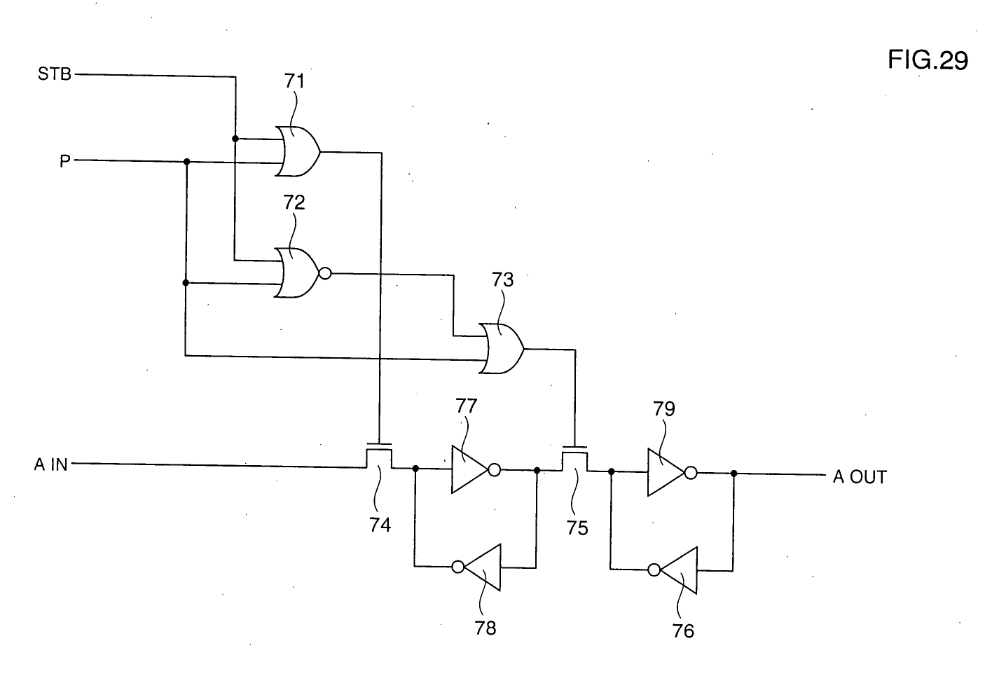

FIG. 29 is a block diagram showing the single bit address register of the address register 64 or the address register 69, and here, showing a bit address register. Reference character Ain denotes 1 bit of an address to be input. Reference character Aout denotes an output of a bit address register.

The bit address register includes a first address latch including inverters 77 and 78 and a second address latch including inverters 79 and 76. The first address latch is connected to the second address latch via a transistor 75 functioning as a gate of the second address latch. The input bit address Ain is connected to the first address latch via a transistor 74 functioning as a gate of the first address latch. An output from the second address latch serves as the output Aout of the bit address register. Here, each of the transistors 74 and 75 is an N-channel transistor. Incidentally, each of the transistors 74 and 75 may be a P-channel transistor.

The bit address register stores therein the two control signals, that is, the PASS signal and the STB signal. The STB signal is sent to an input of an OR gate 71 and an input of a NOR gate 72. The PASS signal is sent to inputs of the OR gates 71 and 73 and the input of the NOR gate 72. In the case where the bit address register is a bit register for the address register 64, the PASS signal is the PASSA signal. In contrast, in the case where the bit address register is a bit register for the address register 69, the PASS signal is the PASSB signal. If the PASS signal is logic HIGH, the transistor 74 is turned ON in response to an output from the OR gate 71 and, further, the transistor 75 is turned ON in response to an output from the OR gate 73. If the transistors 74 and 75 are enabled, the Ain signal passes through the bit address register, to be thus turned into the Aout signal. In contrast, if the PASS signal is logic LOW and the STB signal is logic HIGH, the transistor 74 is turned ON while the transistor 75 is turned OFF. The Ain address is latched to the first address latch and, then, is held in the first address latch. When the STB signal is switched to be logic LOW, the transistor 74 is turned OFF while the transistor 75 is turned ON. Thus, the Ain address stored in the first address latch is transported to the second address latch and, then, becomes the output Aout.

Twelfth Embodiment

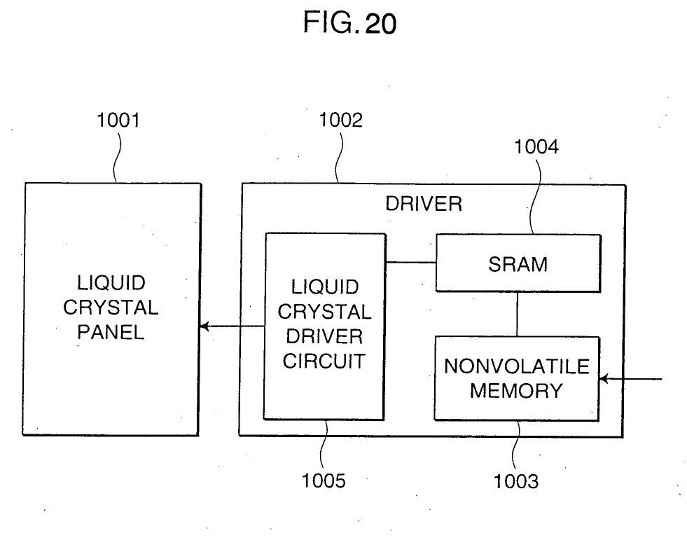

As an application example of the semiconductor memory device, for example, as shown in FIG. 20, a rewritable nonvolatile memory for image adjustment of a liquid crystal panel can be mentioned.

A liquid crystal panel 1001 is driven by a liquid crystal driver 1002. In the liquid crystal driver 1002, a nonvolatile memory 1003, an SRAM 1004 and a liquid crystal driver circuit 1005 are provided. The nonvolatile memory is constructed by the sidewall memory cell, more preferably, any of the semiconductor memory devices of the first to ninth embodiments. The nonvolatile memory 1003 can be rewritten from the outside.

Information stored in the nonvolatile memory 1003 is transferred to the SRAM 1004 at the time of turn-on of the power source of an apparatus. The liquid crystal driver circuit 1005 can read stored information from the SRAM 1004 as necessary. By providing the SRAM, high reading speed of stored information can be achieved.

The liquid crystal driver 1002 may be externally attached to the liquid crystal panel 1001 as shown in FIG. 20 or formed on the liquid crystal panel 1001.

In a liquid crystal panel, tones displayed by applying voltages in multiple grades to pixels are changed. The relation between the given voltage and the displayed tone varies according to products. Consequently, information for correcting variations in each product after completion of the product is stored and correction is made on the basis of the information, thereby enabling the picture qualities of products to be made uniform. It is therefore preferable to mound a rewritable nonvolatile memory for storing correction information. As the nonvolatile memory, it is preferable to use the sidewall memory cell and, particularly, a semiconductor memory device described in the first to ninth embodiments in which the sidewall memory cells are arranged.

Thirteenth Embodiment

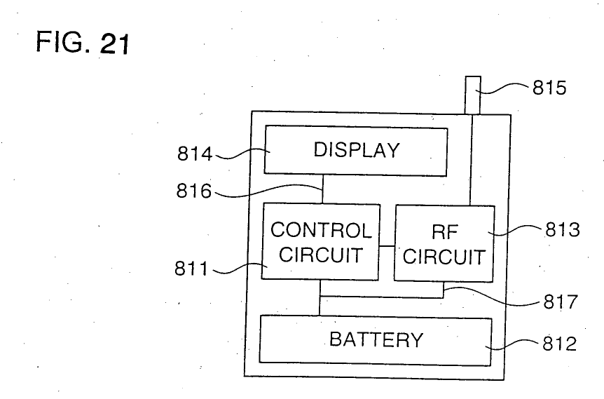

FIG. 21 shows a portable telephone as a portable electronic apparatus in which the semiconductor memory device is assembled.

The portable telephone is constructed mainly by a control circuit 811, a battery 812, an RF (radio frequency) circuit 813, a display 814, an antenna 815, a signal line 816, a power source line 817 and the like. In the control circuit 811, the semiconductor memory device of the present invention is assembled. The control circuit 811 is preferably an integrated circuit using cells having the same structure as a memory circuit cell and a logic circuit cell as described in the tenth embodiment. It facilitates fabrication of the integrated circuit, and the manufacturing cost of the portable electronic apparatus can be particularly reduced.

By using the semiconductor memory device capable of performing high-speed reading operation and whose process of mounting a memory part and a logic circuit part simultaneously is easy for a portable electronic apparatus, the operation speed of the portable electronic apparatus is increased, and the manufacturing cost can be reduced. Thus, a cheap, high-reliability, and high-performance portable electronic apparatus can be obtained.

According to the present invention, an array selection circuit is provided to perform a control on two memory arrays. Consequently, while one of the memory arrays is being re-programmed, data from the other memory array can be read. Thus, an access to the memory arrays can be made at higher speed, and the performance of a computer system using the memory arrays can be improved.

In the sidewall memory cell as a component of the semiconductor memory device, the memory function of the memory functional unit and the transistor operation function of the gate insulating film are separated from each other. Consequently, while maintaining the sufficient memory function, it is easy to reduce the thickness of the gate insulating film and suppress a short channel effect.

Further, as compared with an EEPROM, the value of current flowing between the diffusion regions changes due to rewriting more largely. Therefore, the writing state and erasing state of the semiconductor memory device can be easily discriminated from each other and can raise reliability.

Moreover, the process of forming the memory cell of the present invention has high affinity with the process of forming a normal transistor. Therefore, as compared with the case of forming both a conventional flash memory used as a nonvolatile memory cell and a normal transistor, the number of masks and the number of processes can be dramatically reduced. Thus, the yield of the chip is improved, the cost is reduced, and a cheap and highly-reliable memory cell can be obtained.

Further, according to the present invention, the operating speed of an electronic apparatus having the memory cell of the present invention is improved, the manufacturing cost can be reduced, and cheap and highly-reliable microprocessor, portable electronic apparatus, and display device can be obtained.

What is claimed is:

1. A semiconductor memory device comprising:
a first memory array;
a first address register for storing therein a first address of the first memory array;
a second memory array;
a second address register for storing therein a second address of the second memory array;
a multiplexer connected to the first memory array and the second memory array and to a memory output unit for selectively outputting the first memory array or the second memory array; and
an array selection circuit for selecting the first memory array for re-programming in accordance with an input address and selecting the second memory array for a reading operation, wherein
the array selection circuit sends the first address to the first address register, sends the second address to the second address register, and further, controls the multiplexer, so as to allow the second memory array to be connected to the memory output unit during re-programming of the first memory array, and
each of the first memory array and the second memory array includes a plurality of nonvolatile memory cells each including a gate electrode formed on a semiconductor layer via a gate insulating film, a channel region disposed under the gate electrode, diffusion regions disposed on both sides of the channel region and having a conductive type opposite to that of the channel region, and memory functional units formed on both sides of the gate electrode and having the function of retaining charges.

2. The semiconductor memory device according to claim 1, wherein
the first memory array includes a first memory cell capable of electrically erasing and electrically programming, and
the second memory array includes a second memory cell capable of electrically erasing and electrically programming.

3. The semiconductor memory device according to claim 2, wherein
the re-programming includes erasing and programming of the first and second memory cells.

4. The semiconductor memory device according to claim 1, further comprising:
a state control unit for re-programming.

5. The semiconductor memory device according to claim 4, wherein
the state control unit is a writing state control circuit, which provides an automatic writing function.

6. The semiconductor memory device according to claim 1, wherein
the first memory array is arrayed in a plurality of bit line blocks, and
the semiconductor memory device further comprises a first block decoder connected to the plurality of bit line blocks in the first memory array.

7. The semiconductor memory device according to claim 1, wherein
the first memory array is arrayed in a plurality of word line blocks, and
the semiconductor memory device further comprises a first block decoder connected to the plurality of word line blocks in the first memory array.

8. The semiconductor memory device according to claim 1, wherein
the array selection circuit further includes a latch of the first address sent to the first address register during the re-programming, and a path logic circuit for controlling a latch of the second address sent to the second address register.

9. The semiconductor memory device according to claim 1, wherein
the first memory array includes a first main block, a first booting block having a re-programming/writing lock circuit, and a first parameter block.

10. A microprocessor comprising:
a control unit;
a communication port;
buses connected to the control unit and the communication port; and
a first memory array and a second memory array, both of which are connected to the control unit and the communication port via the buses, wherein
each of the first memory array and the second memory array includes a plurality of nonvolatile memory cells each including a gate electrode formed on a semiconductor layer via a gate insulating film, a channel region disposed under the gate electrode, diffusion regions disposed on both sides of the channel region and having a conductive type opposite to that of the channel region, and memory functional units formed on both sides of the gate electrode and having the function of retaining charges, and
the control unit has access to information stored in the second memory array during re-programming of the first memory array.

11. A microprocessor comprising:
a central processing unit (CPU);
a communication port;
buses connected to the CPU and the communication port; and
a semiconductor memory device connected to the CPU and the communication port via the buses, wherein
the semiconductor memory device formed on a single silicon substrate includes:
(a) a first memory array;
(b) a first address register for storing therein a first address of the first memory array;
(c) a second memory array;
(d) a second address register for storing therein a second address of the second memory array;
(e) a multiplexer having an input unit connected to the first memory array and the second memory array and selectively connecting one of the first memory array and the second memory array to an output unit in the memory device; and
(f) an array selection circuit for selecting the first memory array for input array selecting information and re-programming relative to the first address, so as to respond to memory operation control information capable of reading with respect to the second memory array during the re-programming of the first memory array,
each of the first memory array and the second memory array includes a plurality of nonvolatile memory cells each including a gate electrode formed on a semiconductor layer via a gate insulating film, a channel region disposed under the gate electrode, diffusion regions disposed on both sides of the channel region and having a conductive type opposite to that of the channel region, and memory functional units formed on both sides of the gate electrode and having the function of retaining charges, and
the array selection circuit is connected to the CPU via the bus in order to receive the input array selecting information and the memory operation control information from the CPU, guides the first address to the first address register for re-programming corresponding to the received input array selecting information and memory operation control information, guides the second address to the second address register for reading during the re-programming of the first memory array, enables the second memory array to be read by the CPU during the re-programming of the first memory array, and controls the multiplexer in such a manner as to connect the second memory array to the output unit during the re-programming of the first memory array and the reading of the second memory array.

12. The microprocessor according to claim 11, wherein
each of the first memory array and the second memory array includes a booting block which stores therein a re-programming program for controlling the re-programming of the nonvolatile memory cell, and
the CPU operates based on the re-programming program during the re-programming of the nonvolatile memory cell.

13. The microprocessor according to claim 11, wherein
the nonvolatile memory cell can perform electric erasing and electric programming.

14. The microprocessor according to claim 11, wherein the re-programming includes erasing and programming.

15. The microprocessor according to claim 11, further comprising:
a state control circuit for controlling the re-programming, which is connected to the first and second memory arrays, the first and second address registers and the array selection circuit.

16. The microprocessor according to claim 15, wherein
the state control circuit is a writing state mechanism for controlling automatic writing of the nonvolatile memory cell.
